(19) United States
(12) Patent Application Publication
(10) Pub. No.: US 2011/0304043 A1
(43) Pub. Date: Dec. 15, 2011

(54) SEMICONDUCTOR DEVICE AND MANUFACTURING METHOD OF THE SAME

(75) Inventor: Shinji Wakisaka, Hanno-shi (JP)

(73) Assignee: CASIO COMPUTER CO., LTD., Tokyo (JP)

(21) Appl. No.: 13/152,620

(22) Filed: Jun. 3, 2011

(30) Foreign Application Priority Data
Jun. 11, 2010 (JP) 2010-133868

(51) Int. Cl. H01L 23/498; H01L 21/56

(52) U.S. Cl. 257/737; 438/127; 257/E23.068; 257/E21.502

(57) ABSTRACT

A semiconductor device comprises a semiconductor chip which comprises mode-set terminals, and mode-set wiring lines respectively connected to the mode-set terminals, a sealing layer which covers the semiconductor chip and also covers a land of a first mode-set wiring line that is one of the mode-set wiring lines, the sealing layer including a mode-set via hole formed above a land of a second mode-set wiring line, the second mode-set wiring line being one of the mode-set wiring lines and being different from the first mode-set wiring line, a mode-set embedded conductor provided within the mode-set via hole to be connected to the second mode-set wiring line, and a mode-set conductive pattern which is connected to the mode-set embedded conductor and which is provided on the sealing layer above the land of the first mode-set wiring line.

### CROSS-REFERENCE TO RELATED APPLICATIONS

This application is based upon and claims the benefit of priority from prior Japanese Patent Application No. 2010-133868, filed Jun. 11, 2010, the entire contents of which are incorporated herein by reference.

### BACKGROUND OF THE INVENTION

1. Field of the Invention

The present invention relates to a semiconductor device and a manufacturing method of the same.

2. Description of the Related Art

For example, as described in Jpn. Pat. Appln. KOKAI Publication No. 2008-47734, conventionally, a semiconductor chip is embedded between insulating films stacked by a build-up process. The build-up process is a method of creating a multilayer structure by repeating, for example, the formation of insulating films, the formation of vias, and the formation of conductive patterns. Terminals are provided in the semiconductor chip, and these terminals are connected to a bump via, for example, wiring lines.

Meanwhile, the same semiconductor chip may be used to manufacture sister products of a semiconductor device different in mode such as function, use, style, and format.

If one of the terminals provided in the semiconductor chip is a mode-set terminal, the mode of the semiconductor chip is set to vary, for example, depending on whether the mode-set terminal is in a ground voltage set state or in a nonconnected state (electrically floating state). In such setting, sister products of a semiconductor device different in mode are created by switching a wiring line from the mode-set terminal to the bump into a disconnected state or a conducting state. For example, if the wiring line between the mode-set terminal and the bump is not formed in the manufacture of the semiconductor device, the mode-set terminal and the bump can be in a disconnected state. On the other hand, if the wiring line between the mode-set terminal and the bump is formed, the wiring line from the mode-set terminal to the bump can be in a conducting state.

In order to create sister products of a semiconductor device different in mode, a wiring pattern has to be designed for each mode. Thus, a wiring pattern has to be redesigned to obtain a new mode of semiconductor device. For example, a mask and a reticle for conductive pattern formation have to be made for each mode.

### BRIEF SUMMARY OF THE INVENTION

A semiconductor device according to the present invention comprises:

a semiconductor chip which comprises mode-set terminals, and mode-set wiring lines respectively connected to the mode-set terminals;

a sealing layer which covers the semiconductor chip and also covers a land of a first mode-set wiring line that is one of the mode-set wiring lines, the sealing layer including a mode-set via hole formed above a land of a second mode-set wiring line, the second mode-set wiring line being one of the mode-set wiring lines and being different from the first mode-set wiring line;

a mode-set embedded conductor provided within the mode-set via hole to be connected to the second mode-set wiring line; and

a mode-set conductive pattern which is connected to the mode-set embedded conductor and which is provided on the sealing layer above the land of the first mode-set wiring line.

A semiconductor device manufacturing method according to the present invention comprises:

forming a sealing layer on a semiconductor chip which comprises mode-set terminals, and mode-set wiring lines respectively connected to the mode-set terminals, the sealing layer being formed to cover a land of a first mode-set wiring line which is one of the mode-set wiring lines and a land of a second mode-set wiring line which is one of the mode-set wiring lines and which is different from the first mode-set wiring line;

forming a mode-set via hole in the sealing layer above the land of the second mode-set wiring line; and

forming a mode-set conductive pattern which is connected to the land of the second mode-set wiring line through the mode-set via hole and which is provided on the sealing layer above the land of the first mode-set wiring line.

Another semiconductor device according to the present invention comprises:

a semiconductor chip which comprises a mode-set terminal and a mode-set wiring line, the mode-set wiring line including at least a first land and a second land and being connected to the mode-set terminal;

a sealing layer which covers the semiconductor chip and also covers one of the first land and the second land of the mode-set wiring line, the sealing layer including a mode-set via hole formed above the other of the first land and the second land of the mode-set wiring line;

a mode-set embedded conductor provided within the mode-set via hole to be connected to the other land of the mode-set wiring line; and

mode-set conductive patterns provided on the sealing layer,

wherein a first mode-set conductive pattern which is one of the mode-set conductive patterns is provided on the sealing layer above the one land of the mode-set wiring line, and a second mode-set conductive pattern which is one of the mode-set conductive patterns and which is different from the first mode-set conductive pattern is connected to the mode-set embedded conductor.

Another semiconductor device manufacturing method according to the present invention comprises:

forming a sealing layer on a semiconductor chip which comprises a mode-set terminal, and a mode-set wiring line including at least a first land and a second land and connected to the mode-set terminal, the sealing layer being formed to cover the first land and the second land of the mode-set wiring line;

forming a mode-set via hole above one of the first land and the second land of the mode-set wiring line; and

forming mode-set conductive patterns on the sealing layer,

wherein the mode-set conductive patterns are formed so that a first mode-set conductive pattern is provided on the sealing layer above the other land which is one of the first land and the second land of the mode-set wiring line and which is different from the one land and so that a second mode-set conductive pattern is connected to the one land of the mode-set wiring line through the mode-set via hole, the first mode-set conductive pattern being one of the mode-set conductive patterns, the second mode-set conductive pattern being one of the mode-set conductive patterns and being different from the first mode-set conductive-pattern.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view showing a semiconductor device according to a first embodiment of the present invention;

FIG. 2 is a sectional view showing a semiconductor chip according to the first embodiment;

FIG. 3 is a plan view showing a wiring pattern of the semiconductor chip according to the first embodiment;

FIG. 4 is a plan view showing a wiring pattern of the semiconductor device according to the first embodiment;

FIG. 5 is an enlarged view showing a first example of a portion A shown in FIG. 4;

FIG. 6 is an enlarged view showing a second example of the portion A shown in FIG. 4;

FIG. 7 is an enlarged view showing a third example of the portion A shown in FIG. 4;

FIG. 8 is an enlarged view showing a fourth example of the portion A shown in FIG. 4;

FIG. 9 is an enlarged view showing a fifth example of the portion A shown in FIG. 4;

FIG. 10 is an enlarged view showing a sixth example of the portion A shown in FIG. 4;

FIG. 11 is an enlarged view showing a seventh example of the portion A shown in FIG. 4;

FIG. 12 is a sectional view in one step of a method of manufacturing a semiconductor device according to the first embodiment;

FIG. 13 is a sectional view in a step following FIG. 12;

FIG. 14 is a sectional view in a step following FIG. 13;

FIG. 15 is a sectional view in a step following FIG. 14;

FIG. 16 is a sectional view in a step following FIG. 15;

FIG. 17 is a sectional view in a step following FIG. 16;

FIG. 18 is a sectional view in a step following FIG. 17;

FIG. 19 is a sectional view in a step following FIG. 18;

FIG. 20 is a sectional view in a step following FIG. 19;

FIG. 21 is a plan view showing a wiring pattern of a semiconductor chip according to a second embodiment of the present invention;

FIG. 22 is a plan view showing a wiring pattern of a semiconductor device according to the second embodiment;

FIG. 23 is an enlarged view showing a first example of a portion B shown in FIG. 22;

FIG. 24 is an enlarged view showing a second example of the portion B shown in FIG. 22;

FIG. 25 is an enlarged view showing a third example of the portion B shown in FIG. 22;

FIG. 26 is an enlarged view showing a fourth example of the portion B shown in FIG. 22;

FIG. 27 is an enlarged view showing a fifth example of the portion B shown in FIG. 22;

FIG. 28 is an enlarged view showing a sixth example of the portion B shown in FIG. 22;

FIG. 29 is an enlarged view showing a seventh example of the portion B shown in FIG. 22;

FIG. 30 is an enlarged view showing an eighth example of the portion B shown in FIG. 22;

FIG. 31 is a sectional view showing a semiconductor device according to Modification 1;

FIG. 32 is a sectional view showing a semiconductor chip according to Modification 1;

FIG. 33 is a sectional view showing a semiconductor device according to Modification 2;

FIG. 34 is a sectional view showing a semiconductor chip according to Modification 2;

FIG. 35 is a sectional view showing a semiconductor device according to Modification 3;

FIG. 36 is a sectional view showing a semiconductor chip according to Modification 3;

FIG. 37 is a sectional view in a modified step following FIG. 15; and

FIG. 38 is a sectional view in a step following FIG. 37.

### DETAILED DESCRIPTION OF THE INVENTION

Embodiments of the present invention will be explained below with reference to the drawings. Although various limitations technically preferred to carry out the invention are given to the embodiments described below, the scope of the invention is not limited to the following embodiments and illustrated examples.

### First Embodiment

(1) Configuration of Semiconductor Device

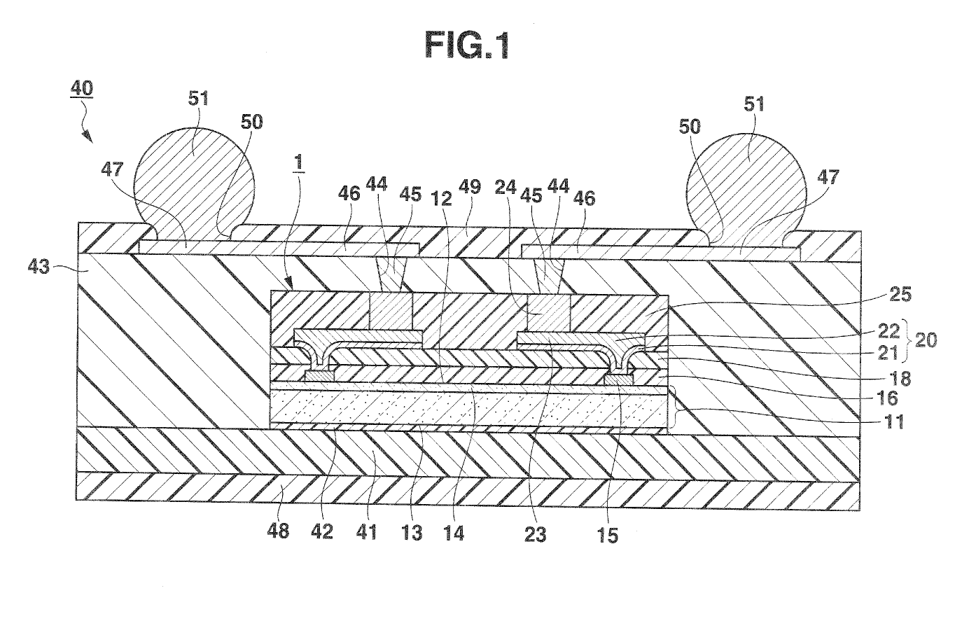

FIG. 1 is a schematic sectional view showing a semiconductor device 40. As shown in FIG. 1, a semiconductor chip 1 including a die obtained by cutting a wafer is embedded in the semiconductor device 40.

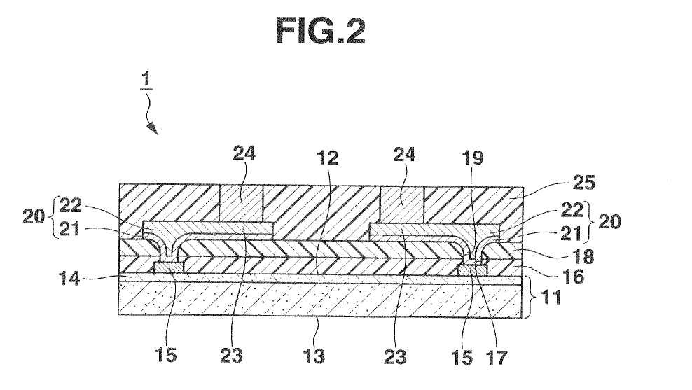

FIG. 2 is a sectional view showing the semiconductor chip 1 before embedded. This semiconductor chip 1 is a so-called chip size package (CSP). The semiconductor chip 1 comprises, for example, a semiconductor substrate 11, terminals 15, a passivation film 16, an insulating film 18, wiring lines 20, columnar electrodes 24, and a protective layer 25. Although two terminals 15, two wiring lines 20, and two electrodes 24 are shown in the sectional view of FIG. 1, there is no limit to the number of terminals 15, wiring lines 20, and electrodes 24.

The semiconductor substrate 11 is made of a semiconductor material such as silicon. The semiconductor substrate 11 has an integrated circuit region 14 in the surface layer of its main surface 12. An integrated circuit such as a transistor is formed in the integrated circuit region 14. The main surface (surface in which the terminals 15 are provided) 12 of the semiconductor substrate 11 is covered with the passivation film 16. The passivation film 16 contains an insulating material such as silicon oxide or silicon nitride. The passivation film 16 is covered with the insulating film 18. The insulating film 18 contains an epoxy resin, a polyimide resin, or some other resin. For example, polyimide (PI), polybenzoxazole (PBO), an epoxy, phenol or silicon plastic material, or a composite of these materials can be used for the insulating film 18. The terminal 15 is a terminal for inputting or outputting, for example, a signal or a predetermined voltage to circuits in the semiconductor substrate 11.

An opening 17 is formed at a position in the passivation film 16 that overlaps the terminal 15. An opening 19 is formed at a position in the insulating film 18 that overlaps the terminal 15. The terminal 15 is located within the openings 17 and 19, and the terminal 15 is not partly or entirely covered with the passivation film 16 and the insulating film 18. The insulating film 18 may not be formed.

The wiring line 20 is formed on the insulating film 18 (on the passivation film 16 when the insulating film 18 is not present). The wiring line 20 has a foundation 21 and a conductive layer 22. The foundation 21 is formed on the insulating film 18, and the conductive layer 22 is formed on the foundation 21. The foundation 21 is obtained by patterning, into a predetermined shape, a seed layer to be a plating seed. A part of the foundation 21 is stacked on the terminal 15, and the foundation 21 is connected to the terminal 15 via the openings 17 and 19. The foundation 21 is made of a conductor. For example, the foundation 21 is a copper (Cu) thin film, a titanium (Ti) thin film, a thin film in which copper is stacked on titanium, or some other metal thin film. The conductive layer 22 is made of copper plating or some other metal plating. When viewed in plan, the conductive layer 22 is patterned into a predetermined shape. The planar shape of the conductive layer 22 is substantially the same as the planar shape of the foundation 21. The conductive layer 22 is thicker than the foundation 21. The wiring line 20 does not have to be a stack of the foundation 21 and the conductive layer 22. For example, the wiring line 20 may be a conductive single layer or a stack of two or more conductive layers.

A part of the wiring line 20 is a land 23. The electrode 24 is formed on the land 23. The electrode 24 is a columnar post electrode, and preferably has a height of about 50 μm to 150 μm. The electrode 24 is made of copper or some other metal. The height (thickness) of the electrode 24 is greater than the thickness of the conductive layer 22. The electrode 24 functions to protect the wiring line 20 against the impact of laser light 67 when a via hole 44 is formed in a later-described sealing layer 43. Moreover, the electrode 24 can ease stress caused between the semiconductor device 40 and an external circuit board as a result of the difference of thermal expansion coefficient between the semiconductor device 40 and the circuit board when a later-described bump 51 is connected to the circuit board. Thus, the separation of connected portions between the semiconductor device 40 and the circuit board can be inhibited.

The protective layer 25 is formed on the insulating film 18, and the wiring line 20 is covered with the protective layer 25. Although the top surface of the electrode 24 is not covered with the protective layer 25, the peripheral surface of the electrode 24 is covered with and protected by the protective layer 25. The front surface of the protective layer 25 is provided to be flush with the top surface of the electrode 24 located slightly higher than the top surface of the electrode 24. When the integrated circuit region 14 does not include any light receiving element such as a light sensor, the protective layer 25 preferably has a light blocking effect to prevent external light from entering the integrated circuit region 14.

The protective layer 25 contains an epoxy resin, a polyimide resin, or some other insulating resin. The protective layer 25 is preferably made of a fiber reinforced resin in which a filler (e.g., glass filler) is blended in an insulating resin (e.g., an epoxy resin or a polyimide resin).

As shown in FIG. 1, the semiconductor device 40 comprises, in addition to the semiconductor chip 1, a base plate 41, the sealing layer 43, an embedded conductor 45, a conductive pattern 46, overcoat layers 48 and 49, and the bump 51.

The base plate 41 includes at least one of a glass fiber reinforced epoxy resin (including a glass fiber epoxy resin), a carbon fiber reinforced epoxy resin (including a carbon fiber epoxy resin), a glass fiber reinforced polyimide resin (including a glass fiber polyimide resin), a carbon fiber reinforced polyimide resin (including a carbon fiber polyimide resin), and some other fiber reinforced resin.

The semiconductor chip 1 is mounted on the front surface of the base plate 41, and the overcoat layer 48 is formed on the rear surface of the base plate 41. The overcoat layer 48 is a solder resist made of a resin material.

The semiconductor substrate 11 and the base plate 41 are bonded together by an intervening adhesive layer 42 so that a rear surface 13 of the semiconductor substrate 11 of the semiconductor chip 1 opposite to the main surface 12 faces the front surface of the base plate 41.

The sealing layer 43 is formed on the base plate 41 around the semiconductor chip 1 and on the semiconductor chip 1 except for the via holes 44. The whole semiconductor chip 1 is covered with the sealing layer 43. The side surface of the stack of the semiconductor substrate 11, the passivation film 16, the insulating film 18, and the protective layer 25 is protected by the sealing layer 43. A part of the front surface of the electrode 24 and the front surface of the protective layer 25 are protected by the sealing layer 43.

The sealing layer 43 includes at least one of a glass fiber reinforced epoxy resin (including a glass fiber epoxy resin), a carbon fiber reinforced epoxy resin (including a carbon fiber epoxy resin), a glass fiber reinforced polyimide resin (including a glass fiber polyimide resin), a carbon fiber reinforced polyimide resin (including a carbon fiber polyimide resin), and some other fiber reinforced resin.

The via hole 44 is formed in the sealing layer 43. The via hole 44 is located above the electrode 24, and overlaps the electrode 24. The embedded conductor 45 is embedded in the via hole 44, and the embedded conductor 45 and the electrode 24 are conducted to each other.

The conductive pattern 46 is formed on the sealing layer 43. The conductive pattern 46 includes at least one of a copper (Cu) film, a titanium (Ti) film, a film in which copper is stacked on titanium, or some other conductive film. When viewed in plan, the conductive pattern 46 is patterned into a predetermined shape. A part of the conductive pattern 46 overlaps the front surface of the embedded conductor 45, and the conductive pattern 46 is conducted to the embedded conductor 45. A part of the conductive pattern 46 is a land 47.

The overcoat layer 49 is formed on the conductive pattern 46 except for the lands 47 and on the sealing layer 43. The conductive pattern 46 is covered with the overcoat layer 49. The overcoat layer 49 is a solder resist made of a resin material. An opening 50 is formed at the position in the overcoat layer 49 that overlaps the land 47 of the conductive pattern 46. The land 47 is located within the opening 50, and the land 47 is not covered with the overcoat layer 49. The bump 51 is formed on the land 47 within the opening 50. The bump 51 may be a solder ball, and its surface may be coated with gold. The terminal 15 is conducted to the bump 51 via the wiring line 20, the electrode 24, the embedded conductor 45, and the conductive pattern 46. Insulating films may be stacked between the sealing layer 43 and the overcoat layer 49 by repeating the formation of insulating films, the drilling of the insulating films, and the formation of conductive patterns (build-up process), and the conductive patterns 46 may be formed between these insulating films.

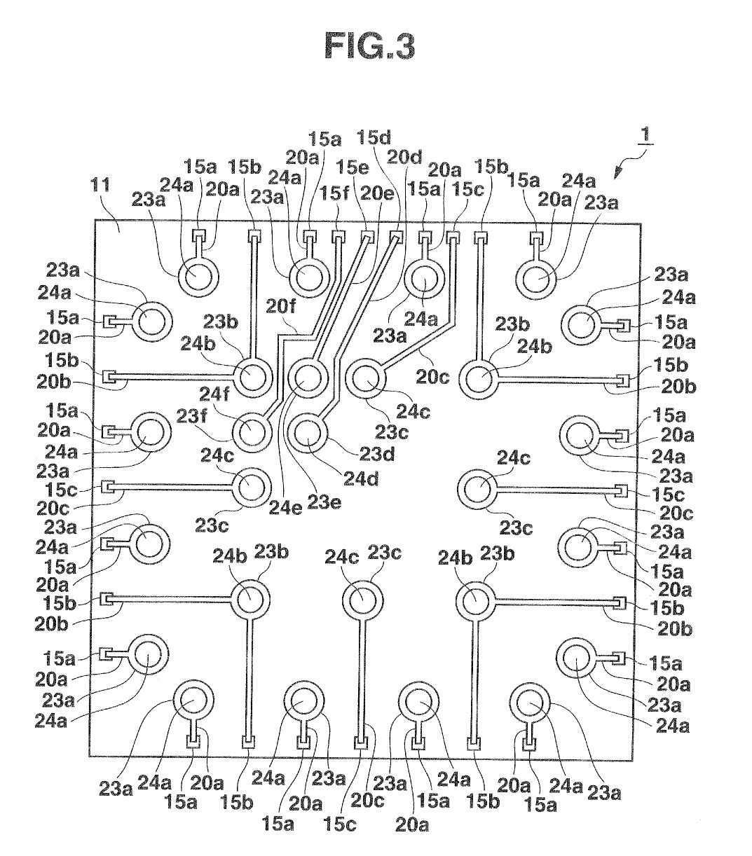

The kinds of terminal 15, wiring line 20, land 23, and electrode 24 that are provided in the semiconductor chip 1 are described with reference to FIG. 3. FIG. 3 is a plan view of the semiconductor chip 1. In FIG. 3, the protective layer 25 is not shown for clarity.

The terminal 15 is classified into a signal terminal 15a, a ground voltage terminal 15b, a power supply voltage terminal 15c, a mode-set first terminal 15d, a mode-set second terminal 15e, and a mode-set third terminal 15f. The terminals 15a to 15f are arranged along the peripheral edge of the main surface 12 of the semiconductor substrate 11.

The signal terminal 15a is a terminal for inputting or outputting signals when the semiconductor chip 1 is in operation.

The ground voltage terminal 15b is a terminal set to a ground voltage.

The power supply voltage terminal 15c is a terminal for inputting a power supply voltage set to a predetermined positive or negative voltage.

The mode-set terminals 15d to 15f serve to determine a mode of the semiconductor chip 1, such as a function, a use, a style, and a format. For example, the mode of the semiconductor chip 1 in which the mode-set terminals 15d to 15f are in a predetermined voltage set state and supplied with a predetermined voltage such as a ground voltage is different from the mode of the semiconductor chip 1 in which the mode-set terminals 15d to 15f are in a nonconnected state. The nonconnected state refers to an electrically floating state produced when the terminals are not conducted to a voltage source. As in Examples 1 to 4, a mode of the semiconductor chip 1 is determined depending on the combination of the predetermined voltage set state and the nonconnected state of the respective mode-set terminals 15d to 15f.

### Example 1

The mode-set terminals 15d to 15f serve to set an initial clock after power on reset of the semiconductor chip 1. The relation of the initial clock setting after the power on reset of the semiconductor chip 1 is determined by the combination of the predetermined voltage set state and the nonconnected state of the mode-set terminals 15d to 15f.

### Example 2

The mode-set terminals 15d to 15f serve to set a memory bus width. A memory bus width (e.g., 32 bits) when the mode-set terminals 15d to 15f are in the predetermined voltage set state is different from a memory bus width (e.g., 64 bits) when the mode-set terminals 15d to 15f are in the nonconnected state.

### Example 3

The mode-set terminals 15d to 15f serve to set data alignment. Data alignment (e.g., big endian) when the mode-set terminals 15d to 15f are in the predetermined voltage set state is different from data alignment (e.g., little endian) when the mode-set terminals 15d to 15f are in the nonconnected state.

### Example 4

The mode-set terminals 15d to 15f serve to set an operation mode of the semiconductor chip 1. An operation mode (e.g., a test mode before shipment) when the mode-set terminals 15d to 15f are in the predetermined voltage set state is different from an operation mode (normal operation mode) when the mode-set terminals 15d to 15f are in the nonconnected state.

The mode set by the mode-set terminals 15d to 15f is not limited to Examples 1 to 4. The mode set by the mode-set terminals 15d to 15f may be a combination of Examples 1 to 4. Although a total of three mode-set terminals 15d to 15f are provided, four or more mode-set terminals may be provided, or one or two mode-set terminals may be provided.

The wiring line 20 is classified into a signal wiring line 20a, a ground voltage wiring line 20b, a power supply voltage wiring line 20c, a mode-set first wiring line 20d, a mode-set second wiring line 20e, and a mode-set third wiring line 20f. The signal wiring line 20a, the ground voltage wiring line 20b, the power supply voltage wiring line 20c, and the mode-set wiring lines 20d to 20f are connected to the signal terminal 15a, the ground voltage terminal 15b, the power supply voltage terminal 15c, and the mode-set terminals 15d to 15f, respectively. Here, one signal terminal 15a is connected to one signal wiring line 20a. Two ground voltage terminals 15b, 15b are connected to one ground voltage wiring line 20b. One power supply voltage terminal 15c is connected to one power supply voltage wiring line 20c.

The land 23 is classified into a signal land 23a, a ground voltage first land 23b, a power supply voltage first land 23c, a mode-set first wiring line land 23d, a mode-set second wiring line land 23e, and a mode-set third wiring line land 23f. The signal land 23a, the ground voltage first land 23b, the power supply voltage first land 23c, and the mode-set wiring line lands 23d to 23f are provided in the signal wiring line 20a, the ground voltage wiring line 20b, the power supply voltage wiring line 20c, and the mode-set wiring lines 20d to 20f, respectively.

The electrode 24 is classified into a signal electrode 24a, a ground voltage electrode 24b, a power supply voltage electrode 24c, a mode-set first electrode 24d, a mode-set second electrode 24e, and a mode-set third electrode 24f. The signal electrode 24a, the ground voltage electrode 24b, the power supply voltage electrode 24c, and the mode-set electrodes 24d to 24f are formed on and thereby conducted to the signal land 23a, the ground voltage first land 23b, the power supply voltage first land 23c, and the mode-set wiring line lands 23d to 23f, respectively.

In the present embodiment, the ground voltage electrode 24b and the power supply voltage electrode 24c are predetermined voltage electrodes.

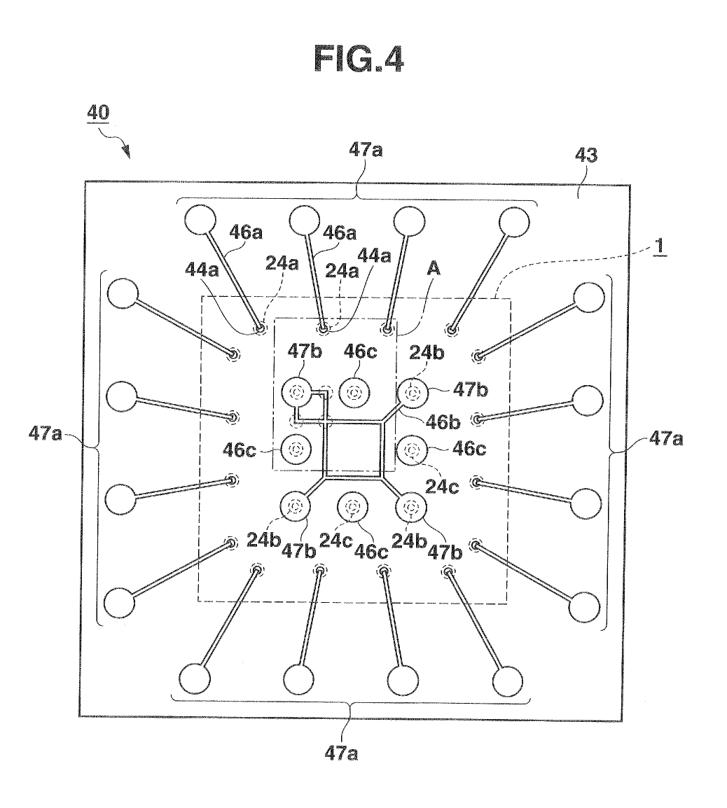

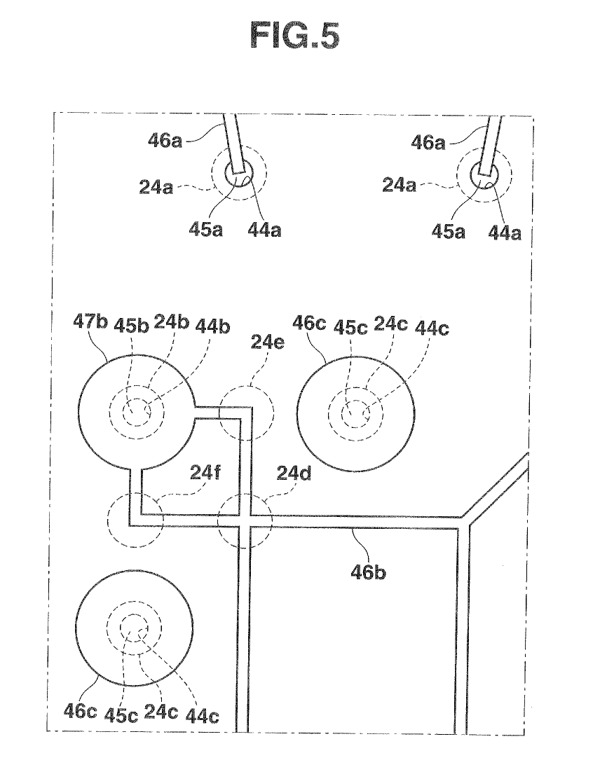

The kinds of via hole 44, embedded conductor 45, conductive pattern 46, and land 47 that are provided in the semiconductor device 40 are described with reference to FIG. 4 to FIG. 11. FIG. 4 is a plan view of the semiconductor device 40. FIG. 5 to FIG. 11 are plan views showing a portion A in FIG. 4 in an enlarged form. The respective modes of the semiconductor chips 1 are shown in FIG. 5 to FIG. 11, and the modes of the semiconductor chips 1 in FIG. 5 to FIG. 11 are different from one another. In FIG. 4 to FIG. 11, the overcoat layer 49 and the bump 51 are not shown for clarity.

The conductive pattern 46 is classified into a signal conductive pattern 46a, a mode-set conductive pattern 46b which is a ground voltage conductive pattern, and a predetermined voltage conductive pattern 46c. The land 47 which is a part or the entirety of the conductive pattern 46 is classified into a signal land 47a, a ground voltage second land 47b, and a predetermined voltage conductive pattern 46c doubling as a land. The predetermined voltage conductive pattern 46c which is a power supply voltage conductive pattern doubling as a land has no linear portion as compared with the other conductive patterns 46, but also functions as a power supply voltage conductive pattern connected to a power supply voltage embedded conductor 45c. The line width of the signal conductive pattern 46a is smaller than the diameter of the signal land 47a, and the line width of the mode-set conductive pattern 46b is smaller than the diameter of the ground voltage second land 47b. Thus, minute drawing/layout of the conductive patterns 46 is facilitated, and the area of contact of the land 47 with the bump 51 is large so that the land 47 and the bump 51 can be well connected to each other.

As shown in FIG. 4, the signal lands 47a are arranged along the peripheral edge of the front surface of the sealing layer 43. The signal land 47a is greater in area than the terminal 15. Moreover, for the convenience of the layout of the conductive patterns 46, the signal land 47a is preferably located above the outside of the semiconductor chip 1 rather than above the semiconductor chip 1. The signal conductive patterns 46a are provided, for example, radially, and one signal land 47a is provided in a peripheral outer end of one signal conductive pattern 46a. In addition, one signal electrode 24a is disposed under a peripheral inner end of one signal conductive pattern 46a.

The ground voltage second lands 47b and the predetermined voltage conductive patterns 46c are alternately arranged circumferentially inside the arrangement of the signal lands 47a. The ground voltage second land 47b is located on the ground voltage electrode 24b, and the predetermined voltage conductive pattern 46c is located on the power supply voltage electrode 24c.

The mode-set conductive pattern 46b is formed into a predetermined shape (see FIG. 4), and all of the ground voltage second lands 47b are conducted to one mode-set conductive pattern 46b. The mode-set conductive pattern 46b crosses over the mode-set electrodes 24d to 24f.

The via hole 44 is classified into a signal via hole 44a, a ground voltage via hole 44b, a power supply voltage via hole 44c, a mode-set first via hole 44d, a mode-set second via hole 44e, and a mode-set third via hole 44f (see FIG. 5 to FIG. 11). The embedded conductor 45 is classified into a signal embedded conductor 45a, a ground voltage embedded conductor 45b, a power supply voltage embedded conductor 45c, a mode-set first embedded conductor 45d, a mode-set second embedded conductor 45e, and a mode-set third embedded conductor 45f (see FIG. 5 to FIG. 11).

In the present embodiment, the ground voltage via hole 44b is a predetermined voltage via hole, and the ground voltage embedded conductor 45b is a predetermined voltage embedded conductor.

Each of the signal embedded conductors 45a is connected, at its lower end, to each of the signal electrodes 24a, and connected, at its upper end, to each of the signal conductive patterns 46a. Each of the ground voltage embedded conductors 45b is connected, at its lower end, to each of the ground voltage electrodes 24b, and connected, at its upper end, to each of the ground voltage second lands 47b. Each of the power supply voltage embedded conductors 45c is connected, at its lower end, to each of the power supply voltage electrodes 24c, and connected, at its upper end, to each of the predetermined voltage conductive patterns 46c.

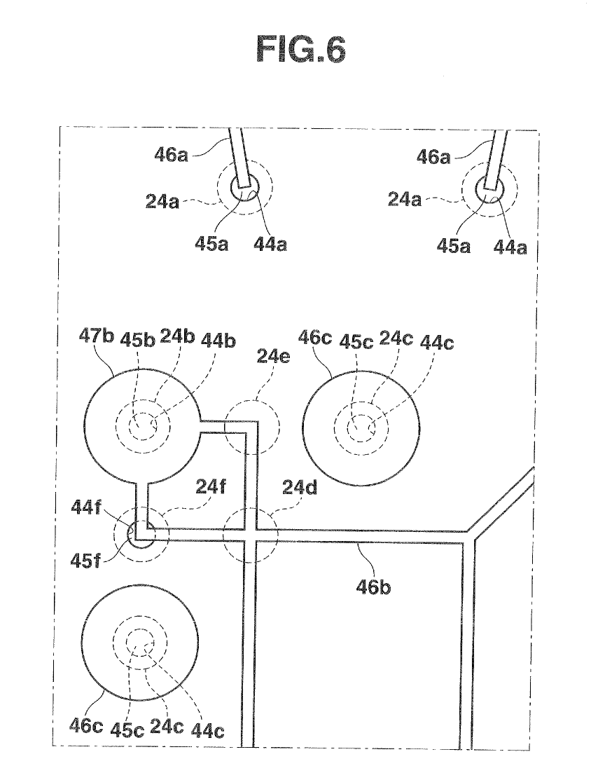

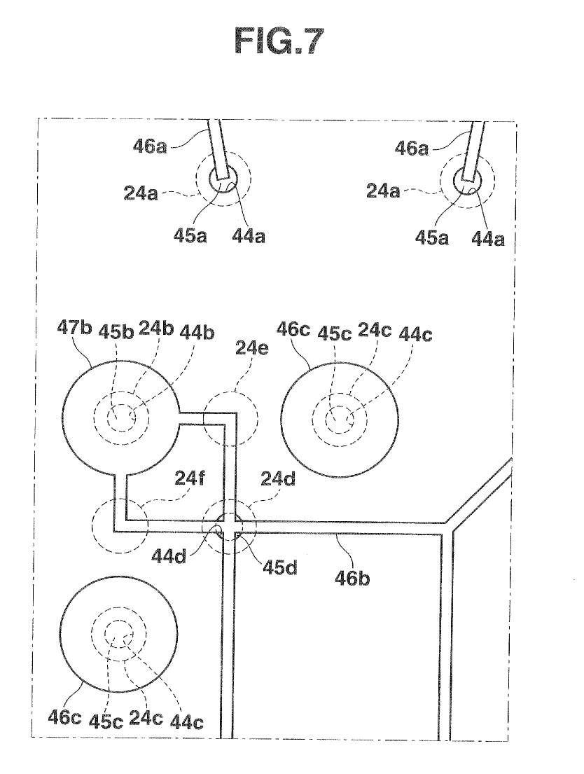

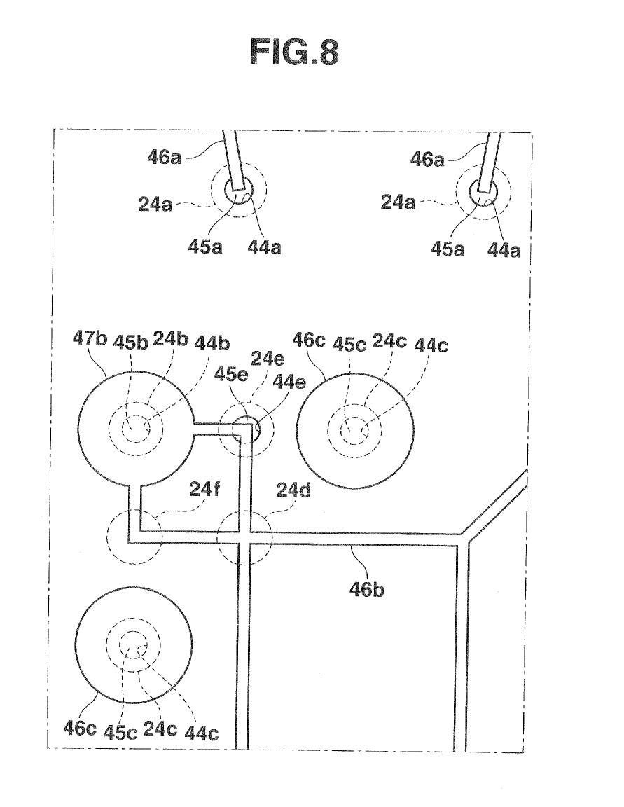

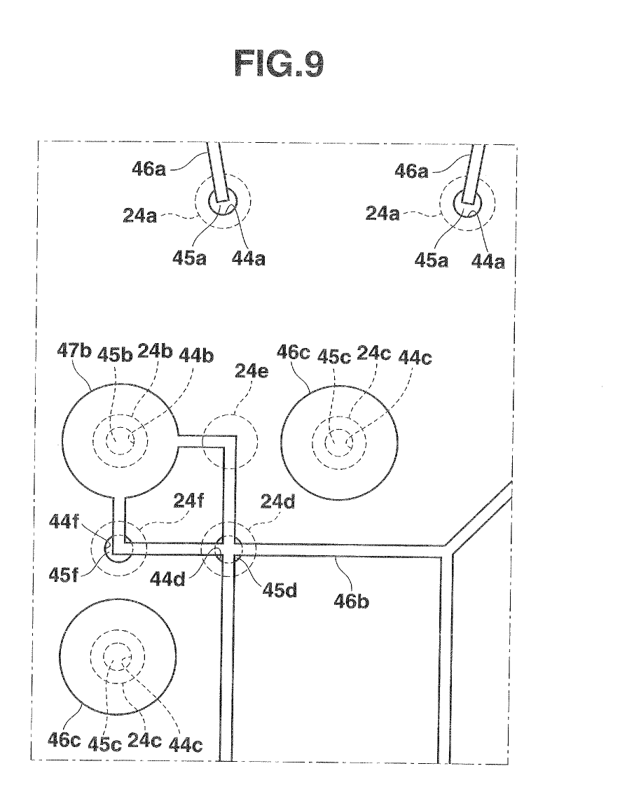

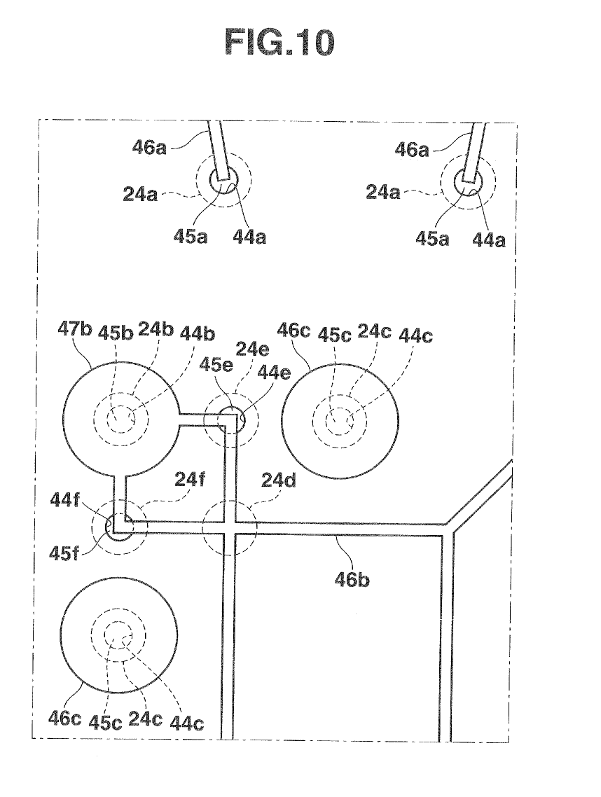

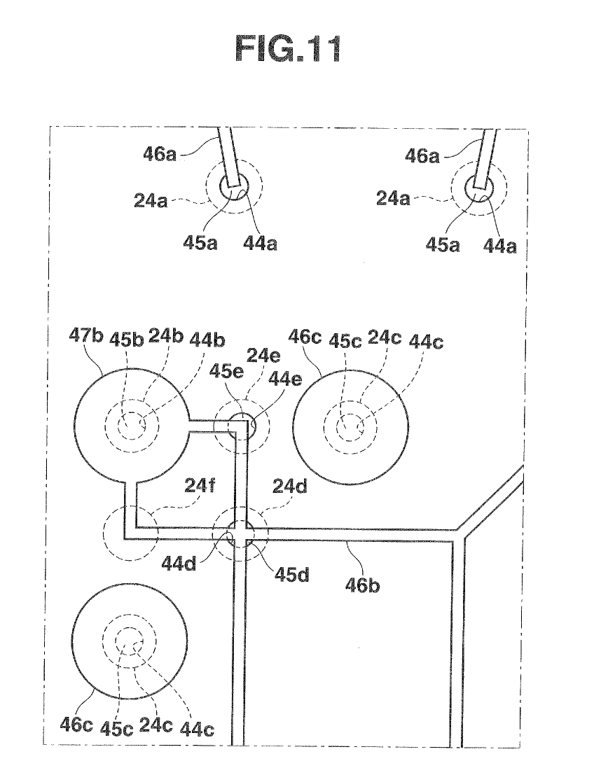

There are cases (see FIG. 7, FIG. 9, and FIG. 11) where both of the mode-set first via hole 44d and the mode-set first embedded conductor 45d are present on the mode-set first electrode 24d and cases (see FIG. 5, FIG. 6, FIG. 8, and FIG. 10) where both are not present on the mode-set first electrode 24d. There are cases (see FIG. 8, FIG. 10, and FIG. 11) where both of the mode-set second via hole 44e and the mode-set second embedded conductor 45e are present on the mode-set second electrode 24e and cases (see FIG. 5, FIG. 6, FIG. 7, and FIG. 9) where both are not present on the mode-set second electrode 24e. There are cases (see FIG. 6, FIG. 9, and FIG. 10) where both of the mode-set third via hole 44f and the mode-set third embedded conductor 45f are present on the mode-set third electrode 24f and cases (see FIG. 5, FIG. 7, FIG. 8, and FIG. 11) where both are not present on the mode-set third electrode 24f.

(A) Both of the mode-set first via hole 44d and the mode-set first embedded conductor 45d are present on the mode-set first electrode 24d (FIG. 7, FIG. 9, and FIG. 11)

The mode-set conductive pattern 46b is connected to the mode-set first embedded conductor 45d, and the mode-set first embedded conductor 45d is connected to the mode-set first electrode 24d. Thus, the mode-set first embedded conductor 45d, the mode-set first electrode 24d, the mode-set first wiring line 20d, and the mode-set first terminal 15d are in the predetermined voltage set state.

(B) Both of the mode-set first via hole 44d and the mode-set first embedded conductor 45d are not present on the mode-set first electrode 24d (FIG. 5, FIG. 6, FIG. 8, and FIG. 10)

As the mode-set first via hole 44d and the mode-set first embedded conductor 45d are not present, the mode-set conductive pattern 46b and the mode-set first electrode 24d are insulated from each other. Thus, the mode-set first electrode 24d, the mode-set first wiring line 20d, and the mode-set first terminal 15d are in the nonconnected state (electrically floating state).

(C) Both of the mode-set second via hole 44e and the mode-set second embedded conductor 45e are present on the mode-set second electrode 24e (FIG. 8, FIG. 10, and FIG. 11)

The mode-set conductive pattern 46b is connected to the mode-set second embedded conductor 45e, and the mode-set second embedded conductor 45e is connected to the mode-set second electrode 24e. Thus, the mode-set second embedded conductor 45e, the mode-set second electrode 24e, the mode-set second wiring line 20e, and the mode-set second terminal 15e are in the predetermined voltage set state.

(D) Both of the mode-set second via hole 44e and the mode-set second embedded conductor 45e are not present on the mode-set second electrode 24e (FIG. 5, FIG. 6, FIG. 7, and FIG. 9)

As the mode-set second via hole 44e and the mode-set second embedded conductor 45e are not present, the mode-set conductive pattern 46b and the mode-set second electrode 24e are insulated from each other. Thus, the mode-set second electrode 24e, the mode-set second wiring line 20e, and the mode-set second terminal 15e are in the nonconnected state (electrically floating state).

(E) Both of the mode-set third via hole 44f and the mode-set third embedded conductor 45f are present on the mode-set third electrode 24f (FIG. 6, FIG. 9, and FIG. 10)

The mode-set conductive pattern 46b is connected to the mode-set third embedded conductor 45f, and the mode-set third embedded conductor 45f is connected to the mode-set third electrode 24f. Thus, the mode-set third embedded conductor 45f, the mode-set third electrode 24f, the mode-set third wiring line 20f, and the mode-set third terminal 15f are in the predetermined voltage set state.

(F) Both of the mode-set third via hole 44f and the mode-set third embedded conductor 45f are not present on the mode-set third electrode 24f (FIG. 5, FIG. 7, FIG. 8, and FIG. 11)

As the mode-set third via hole 44f and the mode-set third embedded conductor 45f are not present, the mode-set conductive pattern 46b and the mode-set third electrode 24f are insulated from each other. Thus, the mode-set third electrode 24f, the mode-set third wiring line 20f, and the mode-set third terminal 15f are in the nonconnected state (electrically floating state).

As in (A) to (F), the mode-set via holes 44d to 44f and the mode-set embedded conductors 45d to 45f are selectively provided so that the states of the mode-set terminals 15d to 15f are set to the predetermined voltage set state or the nonconnected state. As a result, a mode of the semiconductor chip 1 is selectively determined. Thus, the modes of the semiconductor chips 1 in FIG. 5 to FIG. 11 are different from one another. In this way, the semiconductor chip 1 can automatically set a desired mode from multiple modes in accordance with the combination of the predetermined voltage set state and the nonconnected state of the mode-set electrodes 24d to 24f shown in FIG. 5 to FIG. 11. As each of the mode-set via holes 44d to 44f can be patterned in any manner by laser light radiation from a laser, there is no need for a special mask. Moreover, each of the mode-set embedded conductors 45d to 45f can be formed together with the signal embedded conductor 45a, the ground voltage embedded conductor 45b, and the power supply voltage embedded conductor 45c when each of the mode-set via holes 44d to 44f is appropriately formed. Thus, each of the mode-set embedded conductors 45d to 45f can be easily formed.

The set of the mode-set first via hole 44d and the mode-set first embedded conductor 45d, the set of the mode-set second via hole 44e and the mode-set second embedded conductor 45e, and the set of the mode-set third via hole 44f and the mode-set third embedded conductor 45f are all located between the ground voltage second land 47b and the predetermined voltage conductive pattern 46c doubling as a land or between the predetermined voltage conductive patterns 46c, 46c doubling as lands. Therefore, the mode-set conductive pattern can be connected to the land for supplying a predetermined voltage without redundancy.

In each of FIG. 5 to FIG. 11, the conductive patterns 46 (the signal conductive patterns 46a and the mode-set conductive patterns 46h) formed on the sealing layer 43 are substantially equal in shape, position, sizes and range and the lands 47 (the signal lands 47a, the ground voltage second lands 47b, and the predetermined voltage conductive patterns 46c doubling as lands) are substantially equal in shape, position, size, and range.

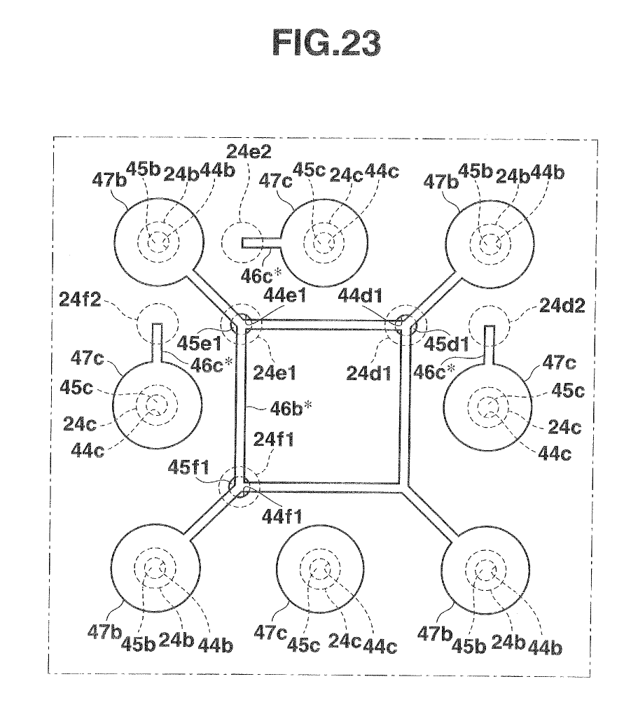

When the semiconductor device 40 described above is mounted on, for example, a circuit board, a ground voltage is supplied to the mode-set conductive pattern 46b and the ground voltage second land 47b from the circuit board, and a power supply voltage is supplied to the predetermined voltage conductive pattern 46c from the circuit board. Various signals are input/output to the signal land 47a. Therefore, when the semiconductor chip 1 is in operation, the ground voltage second land 47b has a given voltage of 0 volts. The ground voltage second lands 47b are preferably located inside the arrangement of the signal lands 47a from the perspective of the easiness of drawing, but are not exclusively located at the positions shown in FIG. 4. Therefore, the ground voltage second lands 47b may be provided at the positions of some of the signal lands 47a or may be provided at the positions of the predetermined voltage conductive patterns 46c. The ground voltage second lands 47b are preferably located inside the arrangement of the signal land 47a because the mode-set conductive patterns 46b can be relatively short. However, as long as the ground voltage second lands 47b are conducted to one another, the mode-set conductive pattern 46b is not limited to the shape shown in FIG. 4. Although the predetermined voltage conductive pattern 46c is used both as a power supply voltage land and a conductive pattern, a linear conductive pattern may be provided in addition to the power supply voltage land, for example, as shown in FIG. 23.

Although the mode-set conductive pattern is the ground voltage conductive pattern in the embodiment described above, the mode-set conductive pattern may be a power supply voltage conductive pattern instead of the ground voltage conductive pattern. In this case, the reference number 15b is the power supply voltage terminal, the reference number 15c is the ground voltage terminal, the reference number 20b is the power supply voltage ring line, the reference number 20c is the ground voltage wiring line, the reference number 23b is the power supply voltage first land, the reference number 23c is the ground voltage first land, the reference number 24b is the power supply voltage electrode, the reference number 24c is the ground voltage electrode, the reference number 44b is the power supply voltage via hole, the reference number 44c is the ground voltage via hole, the reference number 45b is the power supply voltage embedded conductor, the reference number 45c is the ground voltage embedded conductor, a power supply voltage is applied to the mode-set conductive pattern 46b, a ground voltage is applied to the predetermined voltage conductive pattern 46c, the reference number 47b is the power supply voltage second land, and the reference number 47c is the ground voltage second land.

(2) Semiconductor Device Manufacturing Method

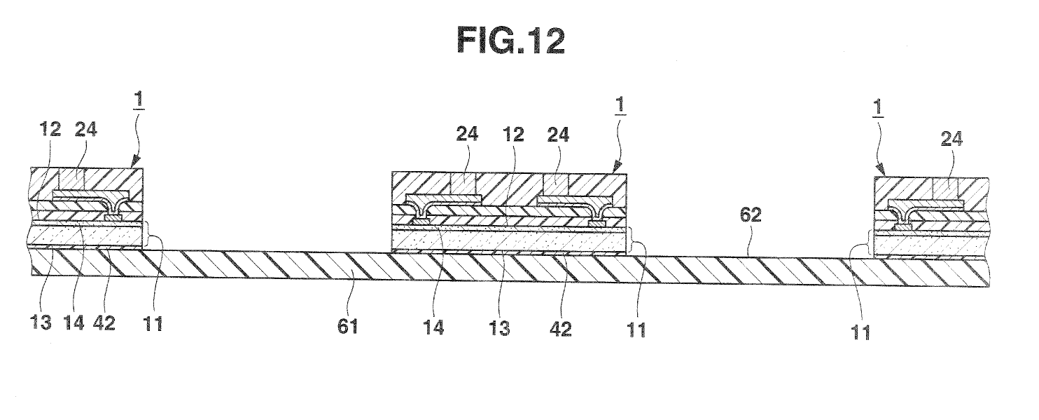

A method of manufacturing the semiconductor device 40 is described with reference to FIG. 12 to FIG. 20. FIG. 12 to FIG. 20 show the process of manufacturing the semiconductor device 40 in order.

As shown in FIG. 12, a mother baseboard 61 made of a fiber reinforced resin is prepared. Semiconductor chips 1 are then mounted on a front surface 62 of the mother baseboard 61, and are arranged in matrix form. Specifically, a rear surface 13 of a semiconductor substrate 11 of each of the semiconductor chips 1 is directed toward the front surface 62 of the mother baseboard 61 to bond the rear surface 13 of the semiconductor substrate 11 of each of the semiconductor chips 1 to the front surface 62 of the mother baseboard 61 by an adhesive layer 42.

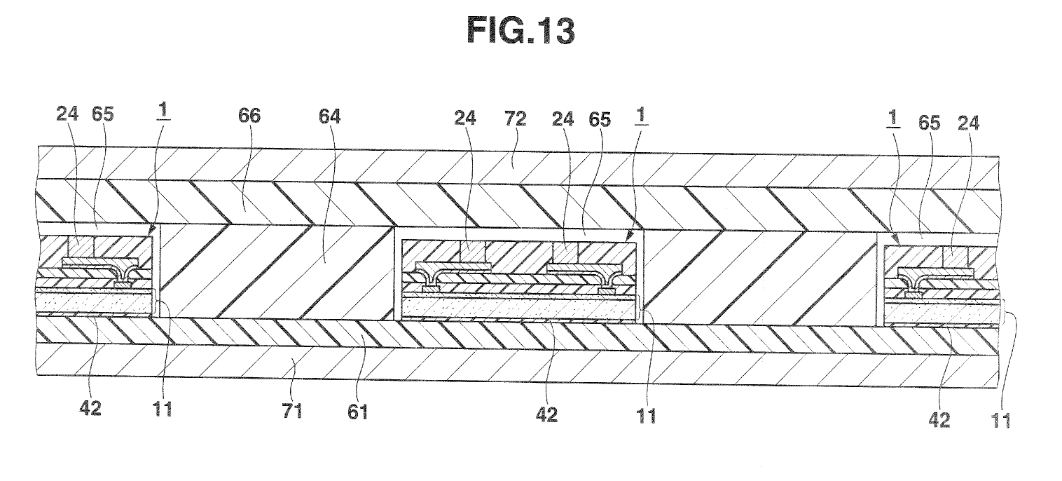

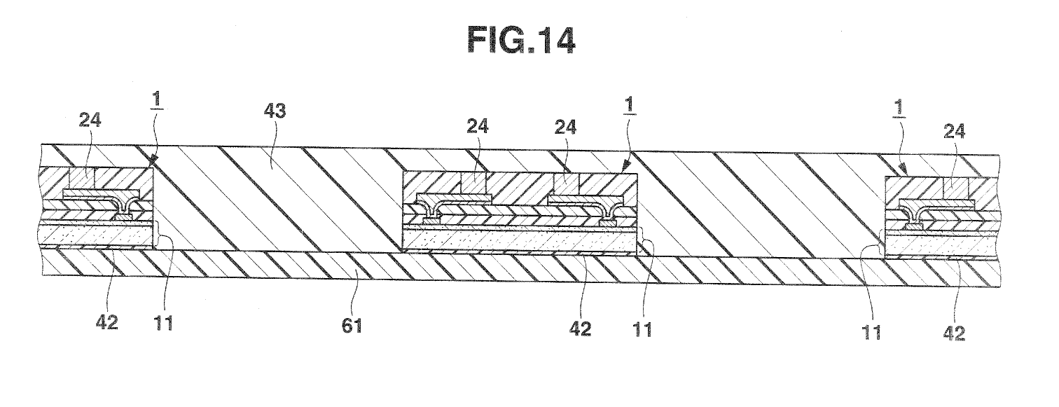

Furthermore, as shown in FIG. 13 and FIG. 14, a sealing layer 43 is formed on the front surface 62 of the mother baseboard 61, and the semiconductor chip 1 is covered with the sealing layer 43. As a result, a protective layer 25 and an electrode 24 (a signal electrode 24a, a ground voltage electrode 24b, a power supply voltage electrode 24c, and mode-set electrodes 24d to 24f) are also covered with the sealing layer 43.

Specifically, the sealing layer 43 is formed from prepregs 64 and 66. The prepregs 64 and 66 are made of a semi-cured (B-stage state) sheet-like fiber reinforced resin. Openings 65 are formed in the prepreg 64, and the openings 65 are arranged in matrix form. No opening is formed in the prepreg 66. In order to form the sealing layer 43, the semiconductor chip 1 is disposed within each of the openings 65 of the prepreg 64, and the prepreg 64 is mounted on the front surface 62 of the mother baseboard 61, and the prepreg 66 is mounted on the prepreg 64 and the semiconductor chip 1. Further, a thermocompression plate 71 is disposed on the rear surface of the mother baseboard 61, and a thermocompression plate 72 is disposed on the front surface of the prepreg 66. Thus, pressure is applied in a direction to bring the heated thermocompression plates 71 and 72 closer to each other so that the prepregs 64 and 66 are deformed and thermally-cured. In this way, the sealing layer 43 is formed from the prepregs 64 and 66. Alternatively, the sealing layer 43 may be formed by coating the mother baseboard 61 and the semiconductor chip 1 with a resin in accordance with various coating methods and curing the coating resin.

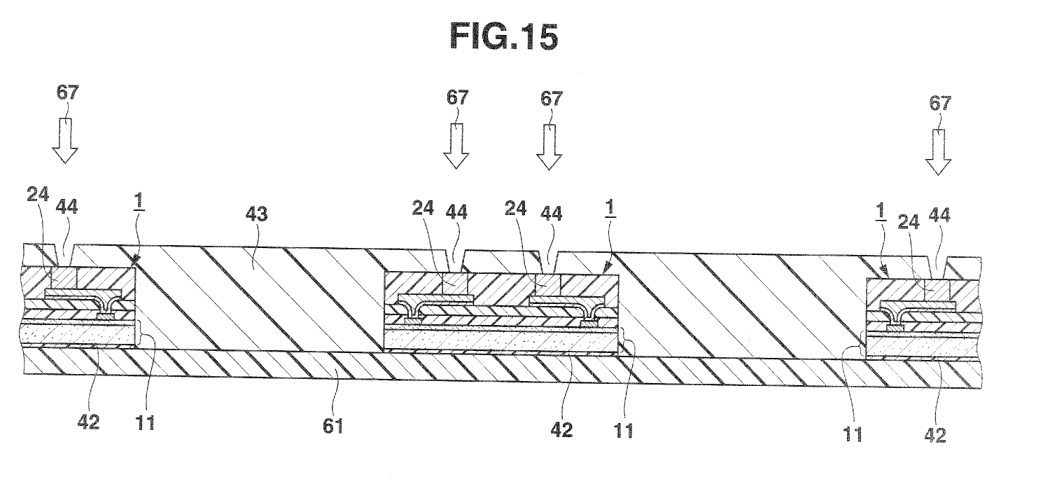

Furthermore, as shown in FIG. 15, a laser in which data on the position (irradiation point of the sealing layer 43) to form a via hole 44 corresponding to each mode is previously stored in an internal memory reads the position data from the memory, and applies laser light 67 to the sealing layer 43 to form the via hole 44. Regardless of the mode, the common laser light 67 is applied to the positions of the electrode 24 corresponding to the signal electrode 24a, the ground voltage electrode 24b, and the power supply voltage electrode 24c. Thus, a signal via hole 44a, a ground voltage via hole 44b, and a power supply voltage via hole 44c among the via holes 44 are formed in the sealing layer 43 by the laser light radiation so that the signal via hole 44a, the ground voltage via hole 44b, and the power supply voltage via hole 44c may reach the signal electrode 24a, the ground voltage electrode 24b, and the power supply voltage electrode 24c. At the same time, the laser light 67 is selectively applied to the mode-set electrodes 24d to 24f depending on the mode, and mode-set via holes 44d to 44f are selectively formed in the sealing layer 43 to produce one of the patterns shown in FIG. 5 to FIG. 11. That is, a mode of the semiconductor chip 1 is determined, and mode-set via holes to be formed are selected from the mode-set via holes 44d to 44f in accordance with the determined mode. It is not possible that all of the mode-set via holes 44d to 44f are formed, but it is possible that all of the mode-set via holes 44d to 44f are not formed.

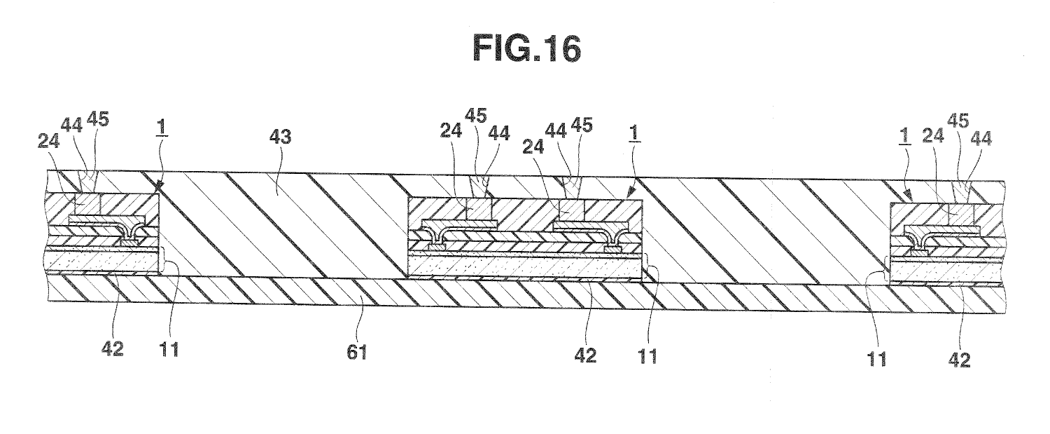

Furthermore, as shown in FIG. 16, the via is filled. That is, an embedded conductor 45 is formed and embedded in the via hole 44. The embedded conductor 45 may be formed by a plating method or by a method that embeds a conductive paste in the via hole 44. The embedded conductor 45 may be formed by some other method.

In this case, a signal embedded conductor 45a, a ground voltage embedded conductor 45b, and a power supply voltage embedded conductor 45c are respectively embedded in the signal via hole 44a, the ground voltage via hole 44b, and the power supply voltage via hole 44c among the via holes 44. At the same time, mode-set embedded conductors 45d to 45f are selectively embedded in the mode-set via holes 44d to 44f (see FIG. 5 to FIG. 11). That is, among the mode-set via holes 44d to 44f, the mode-set embedded conductors 45d to 45f are not embedded under the holes with which the mode-set embedded conductors 45d to 45f are not formed though the mode-set embedded conductors 45d to 45f are embedded under the holes with which the mode-set embedded conductors 45d to 45f are formed.

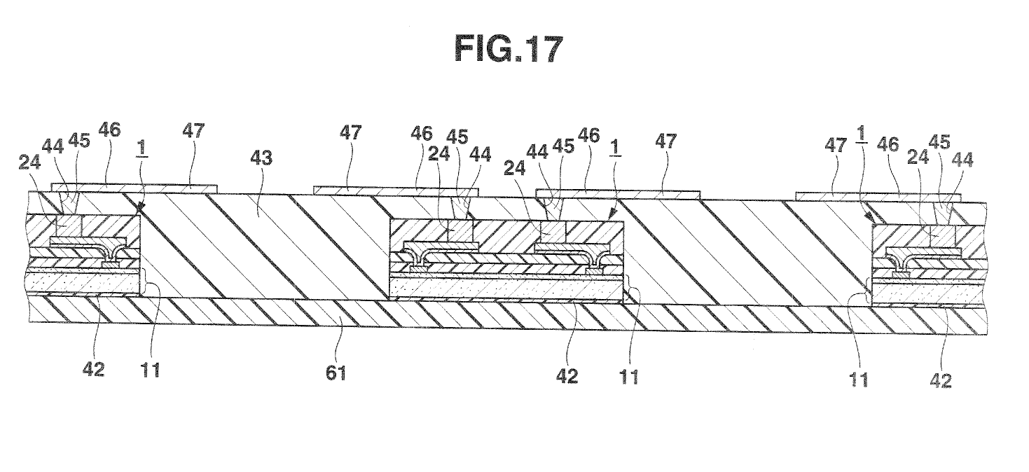

Furthermore, as shown in FIG. 17, a conductive pattern 46 (a signal conductive pattern 46a, a mode-set conductive pattern 46b, and a predetermined voltage conductive pattern 46c) and a land 47 (a signal land 47a, a ground voltage second land 47b, and a predetermined voltage conductive pattern 46c) are formed on the front surface of the sealing layer 43. The conductive pattern 46 and the land 47 are formed by a method such as a full-additive process, a semi-additive process, or a subtractive process.

In forming the conductive pattern 46 and the land 47, the end of the signal conductive pattern 46a is disposed on the signal embedded conductor 45a, the ground voltage second land 47b is disposed on the ground voltage embedded conductor 45b, and the predetermined voltage conductive pattern 46c is disposed on the power supply voltage embedded conductor 45c.

Moreover, in forming the conductive pattern 46 and the land 47, the mode-set conductive pattern 46b is disposed so that the mode-set conductive pattern 46b crosses over all of the mode-set electrodes 24d to 24f. As a result, when the mode-set first via hole 44d and the mode-set first embedded conductor 45d are formed, the mode-set conductive pattern 46b is conducted to the mode-set first electrode 24d by the mode-set first embedded conductor 45d (see FIG. 7, FIG. 9, and FIG. 11). When the mode-set second via hole 44e and the mode-set second embedded conductor 45e are formed, the mode-set conductive pattern 46b is conducted to the mode-set second electrode 24e by the mode-set second embedded conductor 45e (see FIG. 8, FIG. 10, and FIG. 11). When the mode-set third via hole 44f and the mode-set third embedded conductor 45f are formed, the mode-set conductive pattern 46b is conducted to the mode-set third electrode 24f by the mode-set third embedded conductor 45f (see FIG. 6, FIG. 9, and FIG. 10). In each of FIG. 5 to FIG. 11, the same reticle and mask can be used to form the conductive pattern 46 (the signal conductive pattern 46a, the mode-set conductive pattern 46b, and the predetermined voltage conductive pattern 46c) and the land 47 (the signal land 47a, the ground voltage second land 47b, and the predetermined voltage conductive pattern 46c).

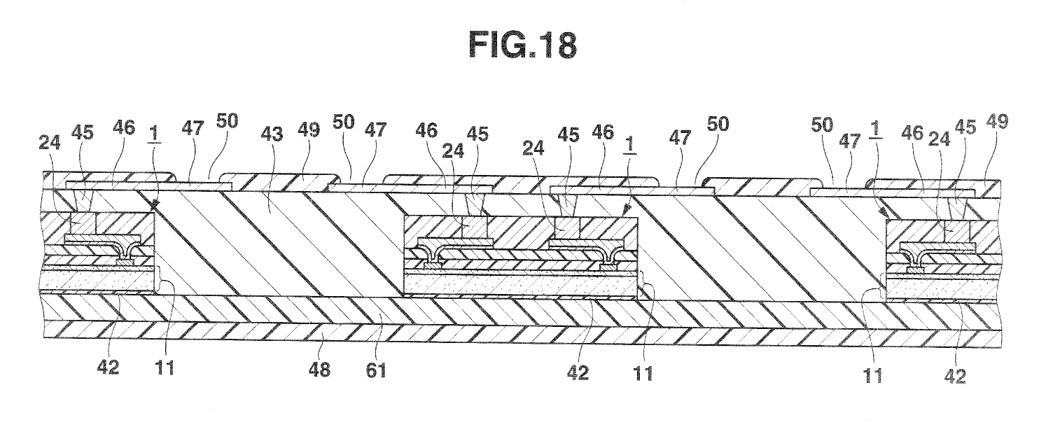

Furthermore, as shown in FIG. 18, an overcoat layer 49 is patterned to cover the conductive pattern 46, the land 47, and the sealing layer 43 with the overcoat layer 49, and expose a part (the land 47) of the conductive pattern 46 through an opening 50 of the overcoat layer 49. Simultaneously with the formation of the overcoat layer 49, an overcoat layer 48 is also formed on a rear surface 63 of the mother baseboard 61.

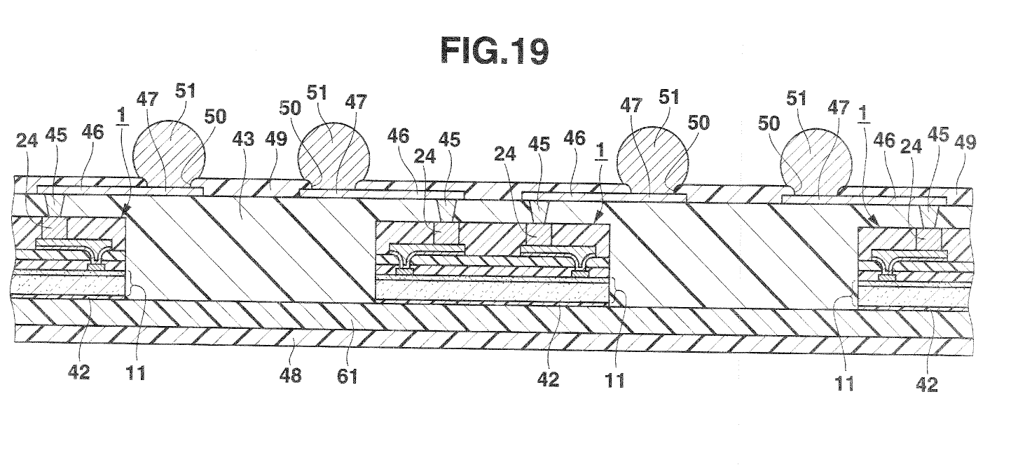

Furthermore, as shown in FIG. 19, a bump 51 such as a solder ball is formed on the land 47 within each opening 50. The bump 51 may not be formed, or the bump 51 may be formed after a later-described dicing process.

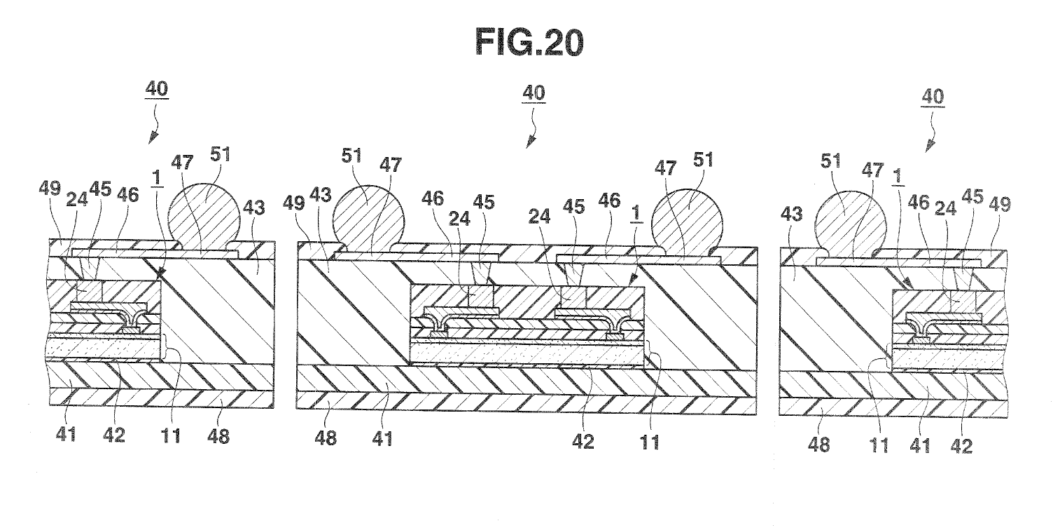

Furthermore, as shown in FIG. 20, the mother baseboard 61, the sealing layer 43, and the overcoat layers 48 and 49 are diced in lattice form and divided for each semiconductor chip 1. As a result, the semiconductor devices 40 are completed. The divided mother baseboard 61 is a base plate 41. When one semiconductor device 40 includes multiple semiconductor chips 1, the mother baseboard 61, the sealing layer 43, and the overcoat layers 48 and 49 are divided for each set of the semiconductor chips 1 instead of dividing the mother baseboard 61, the sealing layer 43, and the overcoat layers 48 and 49 for each semiconductor chip 1.

As described above, according to the present embodiment, sister products of the semiconductor device 40 different in the mode of the semiconductor chip 1 are created by whether to form the mode-set via holes 44d to 44f. That is, a mode of the semiconductor chip 1 is selected by whether to form the mode-set via holes 44d to 44f. Whether to form the mode-set via holes 44d to 44f is determined not by whether to change, for example, the reticle and mask but by whether to apply the laser light 67.

Therefore, when the same semiconductor chip 1 is used to manufacture sister products of the semiconductor device 40 (multiple kinds of semiconductor devices 40) different in the mode of the semiconductor chip 1, the conductive pattern 46 (the signal conductive pattern 46a, the mode-set conductive pattern 46b, and the predetermined voltage conductive pattern 46c) and the land 47 (the signal land 47a, the ground voltage second land 47b, and the predetermined voltage conductive pattern 46c) do not have to be designed for each mode.

Moreover, even if the modes of the semiconductor chips 1 are different, the conductive patterns 46 are equal in shape, position, size, and range, so that there is no need to recreate a program for an inspection process of the conductive pattern 46 for each mode.

Consequently, manufacturing costs can be reduced.

### Second Embodiment

(1) Configuration of Semiconductor Device

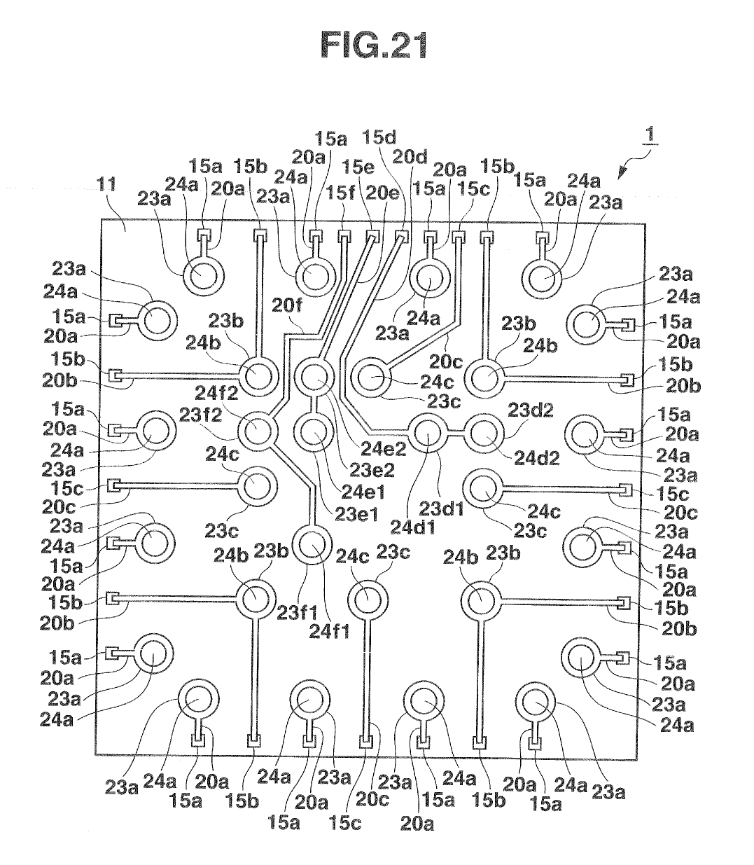

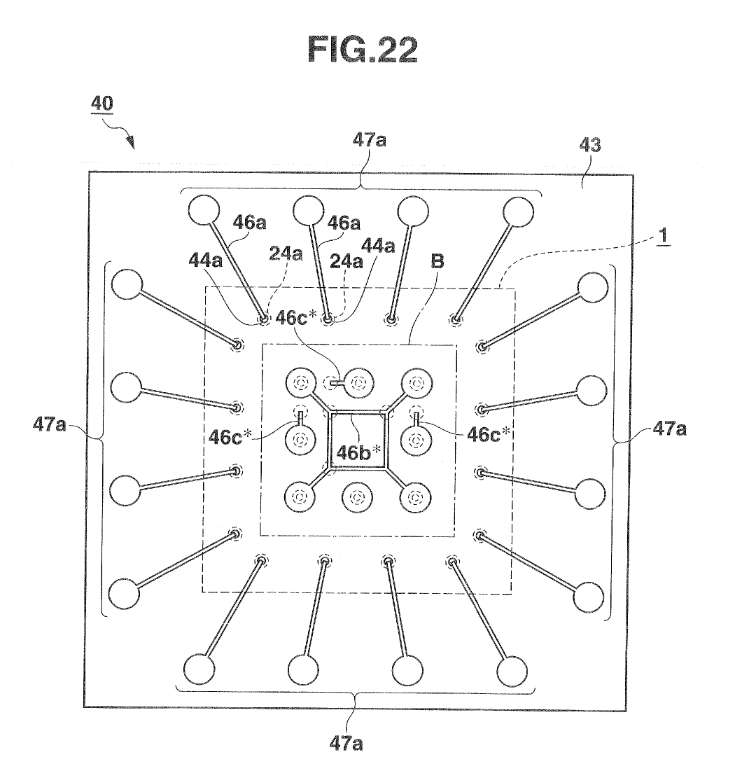

FIG. 21 is a plan view showing a semiconductor chip 1 according to a second embodiment. FIG. 22 is a plan view of a semiconductor device 40 according to the second embodiment. FIG. 23 to FIG. 30 are plan views showing a portion B in FIG. 22 in an enlarged form. The respective modes of the semiconductor chips 1 are shown in FIG. 23 to FIG. 30, and the modes of the semiconductor chips 1 in FIG. 23 to FIG. 30 are different from one another. In FIG. 21, a protective layer 25 is not shown for clarity. In FIG. 22 to FIG. 30, an overcoat layer 49 and a bump 51 are not shown for clarity.

The same reference numbers are assigned to components in the semiconductor device 40 according to the second embodiment that correspond to those in the semiconductor device 40 according to the first embodiment. The difference between the semiconductor device 40 according to the second embodiment and the semiconductor device 40 according to the first embodiment is described below. The components in the semiconductor device 40 according to the second embodiment that correspond to those in the semiconductor device 40 according to the first embodiment are provided in a similar manner except for the points described below.

In the first embodiment described above, a mode of the semiconductor chip 1 is determined depending on the combination of the predetermined voltage set state (the ground voltage set state or power supply voltage set state) and the nonconnected state of the respective mode-set terminals 15d to 15f. On the other hand, in the second embodiment, a mode of the semiconductor chip 1 is determined depending on whether mode-set terminals 15d to 15f are in a first predetermined voltage set state that is a ground voltage set state in which a ground voltage is applied or in a second predetermined voltage set state that is a power supply voltage set state in which a positive or negative power supply voltage different from the ground voltage is applied. This is specifically described below.

As shown in FIG. 21, a terminal 15 is classified into a signal terminal 15a, a ground voltage terminal 15b, a power supply voltage terminal 15c, the mode-set first terminal 15d, the mode-set second terminal 15e, and the mode-set third terminal 15f. This is similar to the first embodiment.

A wiring line 20 is classified into a signal wiring line 20a, a ground voltage wiring line 20b, a power supply voltage wiring line 20c, a mode-set first wiring line 20d, a mode-set second wiring line 20e, and a mode-set third wiring line 20f. This is similar to the first embodiment.

A land 23 is classified into a signal land 23a, a ground voltage first land 23b, a power supply voltage first land 23c, and mode-set first lands 23d1, 23d2, 23e1, 23e2, 23f1 and 23f2. The signal land 23a, the ground voltage first land 23b, and the power supply voltage first land 23c are similar to those in the first embodiment. The mode-set first wiring line first land 23d1 and the mode-set first wiring line second land 23d2 are provided in the mode-set first wiring line 20d. The mode-set second wiring line first land 23e1 and the mode-set second wiring line second land 23e2 are provided in the mode-set second wiring line 20e. The mode-set third wiring line first land 23f1 and the mode-set third wiring line second land 23f2 are provided in the mode-set third wiring line 20f.

An electrode 24 is classified into a signal electrode 24a, a ground voltage electrode 24b, a power supply voltage electrode 24c, mode-set first electrodes 24d1 and 24d2, mode-set second electrodes 24e1 and 24e2, and mode-set third electrodes 24f1 and 24f2. The signal electrode 24a, the ground voltage electrode 24b, and the power supply voltage electrode 24c are similar to those in the first embodiment. The mode-set electrodes 24d1, 24d2, 24e1, 24e2, 24f1 and 24f2 are formed on and conducted to the mode-set wiring line lands 23d1, 23d2, 23e1, 23e2, 23f1 and 23f2.

In the present embodiment, the ground voltage electrode 24b and the power supply voltage electrode 24c are predetermined voltage electrodes.

As shown in FIG. 22 to FIG. 30, a conductive pattern 46 is classified into a signal conductive pattern 46a, a mode-set first conductive pattern 46b* which is a ground voltage conductive pattern, and a mode-set second conductive pattern 46c* which is a power supply voltage conductive pattern. A land 47 is classified into a signal land 47a, a ground voltage second land 47b, and a power supply voltage second land 47c.

In the present embodiment, the mode-set first conductive pattern 46b* and the mode-set second conductive pattern 46c* are mode-set conductive patterns.

The functions of the signal conductive pattern 46a, the mode-set first conductive pattern 46b*, the signal land 47a, and the ground voltage second land 47b are similar to those in the first embodiment. However, the shape of the mode-set first conductive pattern 46b* is different from that in the first embodiment (see FIG. 4 and FIG. 22).

The mode-set first conductive pattern 46b* crosses over the mode-set electrodes 24d1, 24e1 and 24f1. The ground voltage second lands 47b and the power supply voltage second lands 47c are alternately arranged circumferentially inside the arrangement of the signal lands 47a. The power supply voltage second land 47c is connected to the mode-set second conductive pattern 46c*. The mode-set second conductive patterns 46c*, 46c*, 46c* are formed above and connected to the mode-set electrodes 24d2, 24e2 and 24f2, respectively.

In each of FIG. 23 to FIG. 30, the conductive patterns 46 (the signal conductive pattern 46a, the mode-set first conductive pattern 46b*, and the mode-set second conductive pattern 46c*) formed on a sealing layer 43 are substantially equal in shape, position, size, and range, and the lands 47 (the signal land 47a, the ground voltage second land 47b, and the power supply voltage second lands 47c) are substantially equal in shape, position, size, and range.

A via hole 44 is classified into a signal via hole 44a, a ground voltage via hole 44b, a power supply voltage via hole 44c, mode-set first via holes 44d1 and 44d2, mode-set second via holes 44e1 and 44e2, and mode-set third via holes 44f1 and 44f2 (see FIG. 23 to FIG. 30). An embedded conductor 45 is classified into a signal embedded conductor 45a, a ground voltage embedded conductor 45b, a power supply voltage embedded conductor 45c, mode-set first embedded conductors 45d1 and 45d2, mode-set second embedded conductors 45e1 and 45e2, and mode-set third embedded conductors 45f1 and 45f2 (see FIG. 23 to FIG. 30).

In the present embodiment, the ground voltage via hole 44b and the power supply voltage via hole 44c are predetermined voltage via holes, and the ground voltage embedded conductor 45b and the power supply voltage embedded conductor 45c are predetermined voltage embedded conductors.

The signal via hole 44a, the ground voltage via hole 44b, the power supply voltage via hole 44c, the signal embedded conductor 45a, the ground voltage embedded conductor 45b, and the power supply voltage embedded conductor 45c are similar to those in the first embodiment.

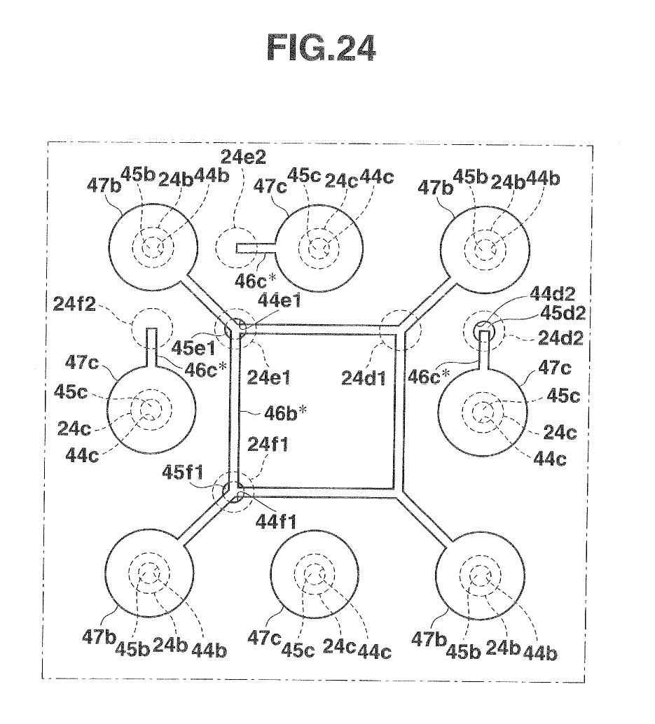

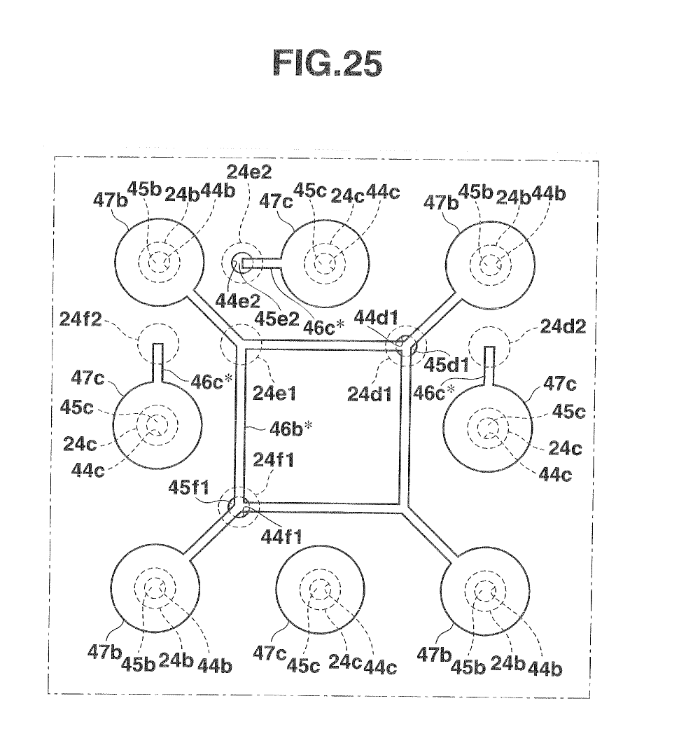

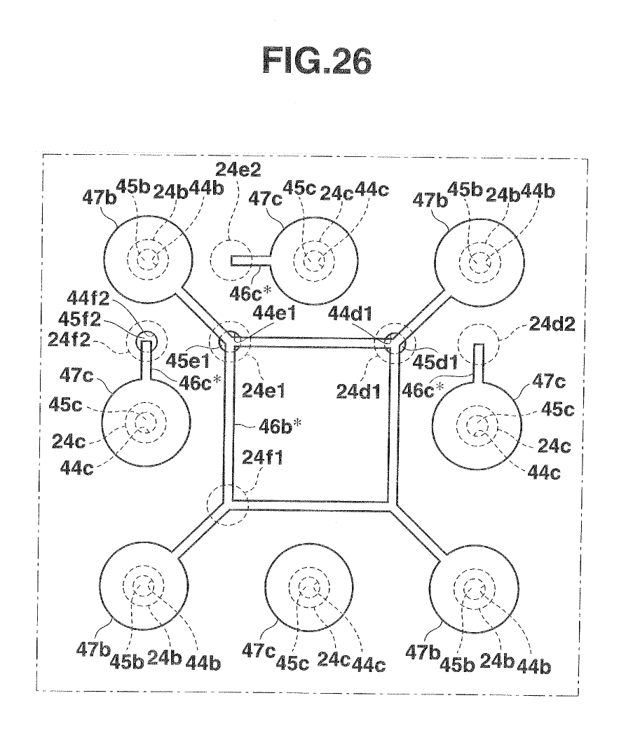

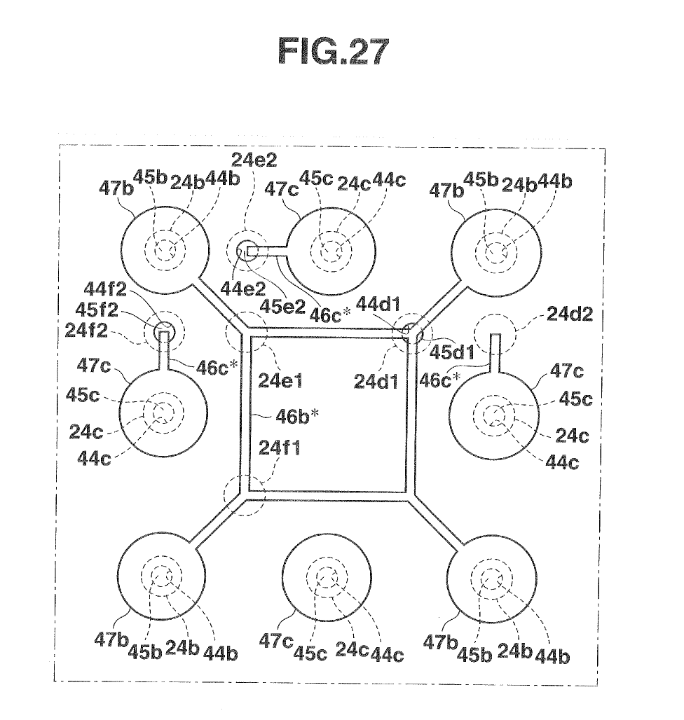

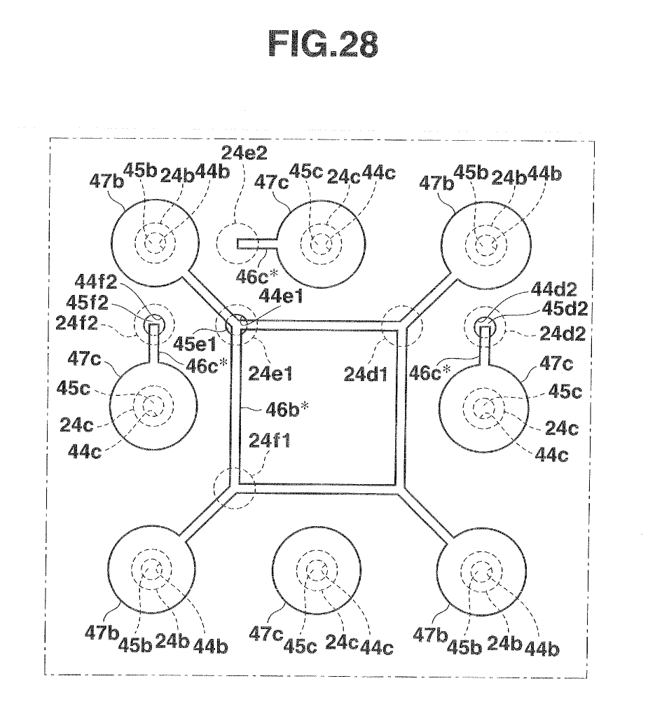

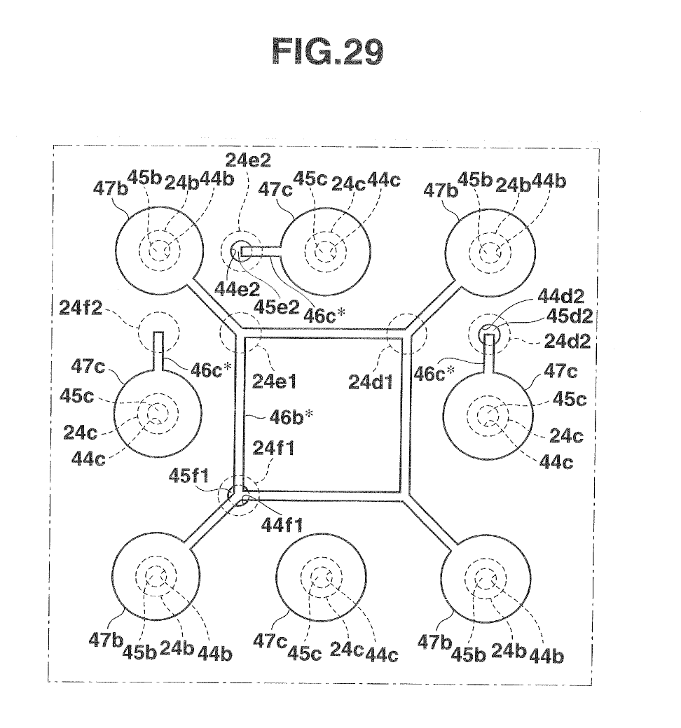

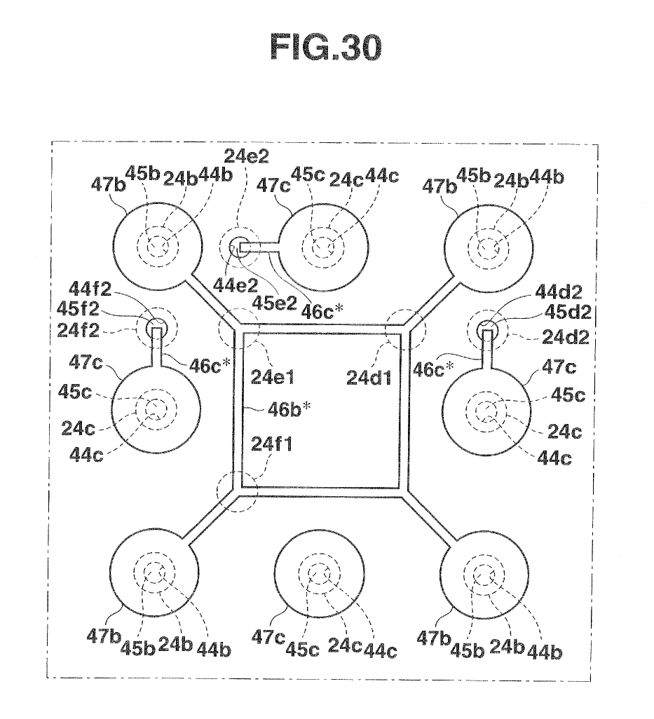

There are cases (see FIG. 23, FIG. 25, FIG. 26, and FIG. 27) where the mode-set first via hole 44d1 and the mode-set first embedded conductor 45d1 are present on the mode-set first electrode 24d1, and the mode-set first via hole 44d2 and the mode-set first embedded conductor 45d2 are not present on the mode-set first electrode 24d2, and cases (see FIG. 24, FIG. 28, FIG. 29, and FIG. 30) where the mode-set first via hole 44d1 and the mode-set first embedded conductor 45d1 are not present on the mode-set first electrode 24d1, and the mode-set first via hole 44d2 and the mode-set first embedded conductor 45d2 are present on the mode-set first electrode 24d2.

There are cases (see FIG. 23, FIG. 24, FIG. 26, and FIG. 28) where the mode-set second via hole 44e1 and the mode-set second embedded conductor 45e1 are present on the mode-set second electrode 24e1, and the mode-set second via hole 44e2 and the mode-set second embedded conductor 45e2 are not present on the mode-set second electrode 24e2, and cases (see FIG. 25, FIG. 27, FIG. 29, and FIG. 30) where the mode-set second via hole 44e1 and the mode-set second embedded conductor 45e1 are not present on the mode-set second electrode 24e1, and the mode-set second via hole 44e2 and the mode-set second embedded conductor 45e2 are present on the mode-set second electrode 24e2.

There are cases (see FIG. 23, FIG. 24, FIG. 25, and FIG. 29) where the mode-set third via hole 44f1 and the mode-set third embedded conductor 45f1 are present on the mode-set third electrode 24f1, and the mode-set third via hole 44f2 and the mode-set third embedded conductor 45f2 are not present on the mode-set third electrode 24f2, and cases (see FIG. 26, FIG. 27, FIG. 28, and FIG. 30) where the mode-set third via hole 44f1 and the mode-set third embedded conductor 45f1 are not present on the mode-set third electrode 24f1, and the mode-set third via hole 44f2 and the mode-set third embedded conductor 45f2 are present on the mode-set third electrode 24f2.

(A) The Mode-Set First Terminal 15d is Set in the First Predetermined Voltage Set State

The mode-set first via hole 44d1 and the mode-set first embedded conductor 45d1 are present on the mode-set first electrode 24d1, and the mode-set first via hole 44d2 and the mode-set first embedded conductor 45d2 are not present on the mode-set first electrode 24d2 (FIG. 23, FIG. 25, FIG. 26, and FIG. 27).

Of the mode-set first electrodes 24d1 and 24d2, the mode-set first electrode 24d1 serves as a specified mode-set electrode, and the mode-set first electrode 24d2 does not function as a specified mode-set electrode. That is, the mode-set first electrode 24d1 is connected to the mode-set first embedded conductor 45d1, the mode-set first embedded conductor 45d1 is connected to the mode-set first conductive pattern. 46b*, and the mode-set first electrode 24d1 and the mode-set first conductive pattern 46b* are conducted to each other by the mode-set first embedded conductor 45d1. On the other hand, as the mode-set first via hole 44d2 and the mode-set first embedded conductor 45d2 are not present, the mode-set first electrode 24d2 and the mode-set second conductive pattern 46c* are insulated from each other. Thus, the mode-set first terminal 15d is set in the first predetermined voltage set state via the ground voltage second land 47b, the mode-set first conductive pattern 46b*, the mode-set first embedded conductor 45d1, the mode-set first electrode 24d1, and the mode-set first wiring line 20d.

(B) The Mode-Set First Terminal 15d is Set in the Second Predetermined Voltage Set State

The mode-set first via hole 44d1 and the mode-set first embedded conductor 45d1 are not present on the mode-set first electrode 24d1, and the mode-set first via hole 44d2 and the mode-set first embedded conductor 45d2 are present on the mode-set first electrode 24d2 (FIG. 24, FIG. 28, FIG. 29, and FIG. 30).

Of the mode-set first electrodes 24d1 and 24d2, the mode-set first electrode 24d2 serves as a specified mode-set electrode, and the mode-set first electrode 24d1 does not function as a specified mode-set electrode. That is, the mode-set first electrode 24d2 is connected to the mode-set first embedded conductor 45d2, the mode-set first embedded conductor 45d2 is connected to the mode-set second conductive pattern 46c*, and the mode-set first electrode 24d2 and the mode-set second conductive pattern 46c* are conducted to each other by the mode-set first embedded conductor 45d2. On the other hand, as the mode-set first via hole 44d1 and the mode-set first embedded conductor 45d1 are not present, the mode-set first electrode 24d1 and the mode-set first conductive pattern 46b* are insulated from each other. Thus, the mode-set first terminal 15d is set in the second predetermined voltage set state via the power supply voltage second land 47e, the mode-set second conductive pattern 46c*, the mode-set first embedded conductor 45d2, the mode-set first electrode 24d2, and the mode-set first wiring line 20d.

(C) The Mode-Set Second Terminal 15e is Set in the First Predetermined Voltage Set State

The mode-set second via hole 44e1 and the mode-set second embedded conductor 45e1 are present on the mode-set second electrode 24e1, and the mode-set second via hole 44e2 and the mode-set second embedded conductor 45e2 are not present on the mode-set second electrode 24e2 (FIG. 23, FIG. 24, FIG. 26, and FIG. 28).

Of the mode-set second electrodes 24e1 and 24e2, the mode-set second electrode 24e1 serves as a specified mode-set electrode, and the mode-set second electrode 24e2 does not function as a specified mode-set electrode. That is, the mode-set second electrode 24e1 is connected to the mode-set second embedded conductor 45e1, the mode-set second embedded conductor 45e1 is connected to the mode-set first conductive pattern 46b*, and the mode-set second electrode 24e1 and the mode-set first conductive pattern 46b* are conducted to each other by the mode-set second embedded conductor 45e1. On the other hand, as the mode-set second via hole 44e2 and the mode-set second embedded conductor 45e2 are not present, the mode-set second electrode 24e2 and the mode-set second conductive pattern 40c* are insulated from each other. Thus, the mode-set second terminal 15e is set in the first predetermined voltage set state via the ground voltage second land 47b, the mode-set first conductive pattern 46b*, the mode-set second embedded conductor 45e1, the mode-set second electrode 24e1, and the mode-set second wiring line 20e.

(D) The Mode-Set Second Terminal 15e is Set in the Second Predetermined Voltage Set State

The mode-set second via hole 44e1 and the mode-set second embedded conductor 45c1 are not present on the mode-set second electrode 24e1, and the mode-set second via hole 44e2 and the mode-set second embedded conductor 45e2 are present on the mode-set second electrode 24e2 (FIG. 25, FIG. 27, FIG. 29, and FIG. 30).

Of the mode-set second electrodes 24e1 and 24e2, the mode-set second electrode 24e2 serves as a specified mode-set electrode, and the mode-set second electrode 24e1 does not function as a specified mode-set electrode. That is, the mode-set second electrode 24e2 is connected to the mode-set second embedded conductor 45e2, the mode-set second embedded conductor 45e2 is connected to the mode-set second conductive pattern 46c*, and the mode-set second electrode 24e2 and the mode-set second conductive pattern 46c* are conducted to each other by the mode-set second embedded conductor 45e2. On the other hand, as the mode-set second via hole 44e1 and the mode-set second embedded conductor 45e1 are not present, the mode-set second electrode 24e1 and the mode-set first conductive pattern 46b* are insulated from each other. Thus, the mode-set second terminal 15e is set in the second predetermined voltage set state via the power supply voltage second land 47c, the mode-set second conductive pattern 46c*, the mode-set second embedded conductor 45e2, the mode-set second electrode 24e2, and the mode-set second wiring line 20e.

(E) The Mode-Set Third Terminal 15f is Set in the First Predetermined Voltage Set State

The mode-set third via hole 44f1 and the mode-set third embedded conductor 45f1 are present on the mode-set third electrode 24f1, and the mode-set third via hole 44f2 and the mode-set third embedded conductor 45f2 are not present on the mode-set third electrode 24f2 (FIG. 23, FIG. 24, FIG. 25, and FIG. 29).

Of the mode-set third electrodes 24f1 and 24f2, the mode-set third electrode 24f1 serves as a specified mode-set electrode, and the mode-set third electrode 24f2 does not function as a specified mode-set electrode. That is, the mode-set third electrode 24f1 is connected to the mode-set third embedded conductor 45f1, the mode-set third embedded conductor 45f1 is connected to the mode-set first conductive pattern 46b*, and the mode-set third electrode 24f1 and the mode-set first conductive pattern 46b* are conducted to each other by the mode-set third embedded conductor 45f1. On the other hand, as the mode-set third via hole 41f2 and the mode-set third embedded conductor 45f2 are not present, the mode-set third electrode 24f2 and the mode-set second conductive, pattern 46c* are insulated from each other. Thus, the mode-set third terminal 15f is set in the first predetermined voltage set state via the ground voltage second land 47b, the mode-set first conductive pattern 46b*, the mode-set third embedded conductor 45f1, the mode-set third electrode 24f1, and the mode-set third wiring line 20f.

(F) The Mode-Set Third Terminal 15f is Set in the Second Predetermined Voltage Set State

The mode-set third via hole 44f1 and the mode-set third embedded conductor 45f1 are not present on the mode-set third electrode 24f1, and the mode-set third via hole 44f2 and the mode-set third embedded conductor 45f2 are present on the mode-set third electrode 24f2 (FIG. 26, FIG. 27, FIG. 28, and FIG. 30).

Of the mode-set third electrodes 24f1 and 24f2, the mode-set third electrode 24f2 serves as a specified mode-set electrode, and the mode-set third electrode 24f1 does not function as a specified mode-set electrode. That is, the mode-set third electrode 24f2 is connected to the mode-set third embedded conductor 45f2, the mode-set third embedded conductor 45f2 is connected to the mode-set second conductive pattern 46c*, and the mode-set first electrode 24d2 and the mode-set second conductive pattern 46c* are conducted to each other by the mode-set third embedded conductor 45f2. On the other hand, as the mode-set third via hole 44f1 and the mode-set third embedded conductor 45f1 are not present, the mode-set third electrode 24f1 and the mode-set first conductive pattern 46b* are insulated from each other. Thus, the mode-set third terminal 15f is set in the second predetermined voltage set state via the power supply voltage second land 47c, the mode-set second conductive pattern 46c*, the mode-set third embedded conductor 45f2, the mode-set third electrode 24f2, and the mode-set third wiring line 20f.

As in (A) to (F), the mode-set via holes 44d1, 44d2, 44e1, 44e2, 44f1 and 44f2 and the mode-set embedded conductors 45d1, 45d2, 45e1, 45e2, 45f1 and 45f2 are selectively provided so that the states of the mode-set terminals 15d to 15f are set to the first predetermined voltage set state or the second predetermined voltage set state. As a result, a mode of the semiconductor chip 1 is selectively determined. Thus, the modes of the semiconductor chips 1 in FIG. 23 to FIG. 30 can be different from one another.

When the semiconductor device 40 according to the second embodiment is mounted on, for example, a circuit board, a ground voltage is supplied to the ground voltage second land 47b from the circuit board, and a power supply voltage having positive and/or negative potentials different from the ground voltage is supplied to the mode-set second conductive pattern 46c* from the circuit board. Various signals are input/output to the signal land 47a. Therefore, when the semiconductor chip 1 is in operation, the ground voltage second land 47b has a given voltage of 0 volts. The second land 47b may not be intended for the ground voltage, and a constant voltage different in level from the ground voltage and the power supply voltage may be input to the second land 47b. In this case, one of conductive pattern sets comprising the land 47, the conductive pattern 46, the embedded conductor 45, the electrode 24, the wiring line 20, and the terminal 15 is intended for the ground voltage, and a ground voltage is supplied from the circuit board to the land 47 of the conductive pattern set intended for the ground voltage.

Although two lands (the mode-set first wiring line first land 23d1 and the mode-set first wiring line second land 23d2) are provided in the mode-set first wiring line 20d, two or more lands may be provided. In this case, the mode-set electrode is provided on each of the three or more mode-set lands including the mod set first wiring line first land 23d1 and the mode-set first wiring line second land 23d2, so that the number of the mode-set electrodes is three or more including the mode-set first electrodes 24d1 and 24d2. Moreover, not only the ground voltage electrode 24b and the power supply voltage electrode 24c but also an additional predetermined voltage electrode penetrates the protective layer 25, and the wiring line 20 and the terminal 15 that are conducted to the additional predetermined voltage electrode are provided in the semiconductor chip 1. Thus, there are also three or more kinds of predetermined voltage electrodes including the ground voltage electrodes 24b and the power supply voltage electrodes 24c. Further, in addition to the mode-set first conductive pattern 46b* and the mode-set second conductive pattern 46c*, an additional mode-set second conductive pattern (a constant voltage different from the power supply voltage and the ground voltage is input to the additional mode-set second conductive pattern) is formed on the front surface of the sealing layer 43, and there are three or more kinds of mode-set predetermined voltage conductive patterns including the mode-set first conductive pattern 46b* and the mode-set second conductive pattern 46c*. These mode-set conductive patterns are formed on the front surface of the sealing layer 43 to respectively overlap the three or more kinds of mode-set predetermined voltage conductive electrodes including the ground voltage electrode 24b and the power supply voltage electrode 24c. Three or more kinds of predetermined voltage via holes including the ground voltage via hole 44b and the power supply voltage via hole 44c are formed in the sealing layer 43, and these predetermined voltage via holes reach the front surface of the sealing layer 43 through the three or more kinds of predetermined voltage electrodes including the ground voltage electrode 24b and the power supply voltage electrode 24c, respectively. The predetermined voltage embedded conductors are respectively embedded in these predetermined voltage via holes, and the three or more kinds of predetermined voltage electrodes are respectively conducted to the three or more kinds of mode-set conductive patterns by the predetermined voltage embedded conductors. Moreover, the mode-set conductive patterns are formed on the front surface of the sealing layer 43 to respectively overlap three or more kinds of mode-set electrodes including the mode-set first electrodes 24d1 and 24d2. The mode-set via hole is formed in the sealing layer 43 on one of the three or more mode-set electrodes including the mode-set first electrodes 24d1 and 24d2, and the mode-set embedded conductor is embedded in this mode-set via hole. Thus, one of the three or more mode-set electrodes including the mode-set first electrodes 24d1 and 24d2 is conducted to one of the three or more kinds of mode-set conductive patterns including the mode-set first conductive pattern 46b* and the mode-set second conductive pattern 46c* by the mode-set embedded conductor.

The same applies to the case where three or more lands are provided in the mode-set second wiring line 20e. The same applies to the case where three or more lands are provided in the mode-set third wiring line 20f.

As in (Example 1) to (Example 4) according to the first embodiment, the modes include, for example, an initial clock setting after the power on reset of the semiconductor chip 1, a memory bus width setting, a data alignment setting, and an operation mode setting of the semiconductor chip 1.

(2) Semiconductor Device Manufacturing Method

A method of manufacturing the semiconductor device 40 according to the second embodiment is described.

The method according to the second embodiment is similar to that according to the first embodiment from the step of mounting semiconductor chips 1 on a front surface 62 of a mother baseboard 61 to the step of forming a sealing layer 43 (see FIG. 12 to FIG. 14).

Furthermore, as shown in FIG. 15, laser light 67 is applied to the sealing layer 43 to form a via hole. The laser light 67 is applied to parts of the electrode 24 corresponding to a signal electrode 24a, a ground voltage electrode 24b, and a power supply voltage electrode 24c. Thus, a signal via hole 44a, a ground voltage via hole 44b, and a power supply voltage via hole 44c among via holes 44 are formed in the sealing layer 43 by the application of the laser light so that the signal via hole 44a, the ground voltage via hole 44b, and the power supply voltage via hole 44c may respectively reach the signal electrode 24a, the ground voltage electrode 24b, and the power supply voltage electrode 24c.

At the same time, a laser in which data on the position (irradiation point of the sealing layer 43) to form the via hole 44 corresponding to each mode is previously stored reads the position data from a memory, and applies the laser light 67 to the sealing layer 43 on one of a mode-set first electrode 24d1 and a mode-set first electrode 24d2 to form one of a mode-set first via hole 44d1 and a mode-set first via hole 44d2 in the sealing layer 43. The laser also applies the laser light 67 to the sealing layer 43 on one of a mode-set second electrode 24e1 and a mode-set second electrode 24e2 to form one of a mode-set second via hole 44e1 and a mode-set second via hole 44e2 in the sealing layer 43. The laser also applies the laser light 67 to the sealing layer 43 on one of a mode-set third electrode 24f1 and a mode-set third electrode 24f2 to form one of a mode-set third via hole 44f1 and a mode-set third via hole 44f2 in the sealing layer 43 (see FIG. 23 to FIG. 30).

Furthermore, as shown in FIG. 16, a signal embedded conductor 45a, a ground voltage embedded conductor 45b, and a power supply voltage embedded conductor 45c are respectively embedded in the signal via hole 44a, the ground voltage via hole 44b, and the power supply voltage via hole 44c among the via holes 44.

When the mode-set first via hole 44d1 is formed, a mode-set first embedded conductor 45d1 is embedded in the mode-set first via hole 44d1 simultaneously with the formation of the signal embedded conductor 45a, the ground voltage embedded conductor 45b, and the power supply voltage embedded conductor 45c (see FIG. 23, FIG. 25, FIG. 26, and FIG. 27).

When the mode-set first via hole 44d2 is formed, a mode-set first embedded conductor 45d2 is embedded in the mode-set first via hole 44d2 simultaneously with the formation of the signal embedded conductor 45a, the ground voltage embedded conductor 45b, and the power supply voltage embedded conductor 45c (see FIG. 24, FIG. 28, FIG. 29, and FIG. 30).

When the mode-set second via hole 44e1 is formed, a mode-set second embedded conductor 45e1 is embedded in the mode-set second via hole 44e1 simultaneously with the formation of the signal embedded conductor 45a, the ground voltage embedded conductor 45b, and the power supply voltage embedded conductor 45c (see FIG. 23, FIG. 24, FIG. 26, and FIG. 28).

When the mode-set second via hole 44e2 is formed, a mode-set second embedded conductor 45e2 is embedded in the mode-set second via hole 44e2 simultaneously with the formation of the signal embedded conductor 45a, the ground voltage embedded conductor 45b, and the power supply voltage embedded conductor 45c (see FIG. 25, FIG. 27, FIG. 29, and FIG. 30).

When the mode-set third via hole 44f1 is formed, a mode-set third embedded conductor 45f1 is embedded in the mode-set third via hole 44f1 simultaneously with the formation of the signal embedded conductor 45a, the ground voltage embedded conductor 45b, and the power supply voltage embedded conductor 45c (see FIG. 23, FIG. 24, FIG. 25, and FIG. 29).

When the mode-set third via hole 44f2 is formed, a mode-set third embedded conductor 45f2 is embedded in the mode-set third via hole 44f2 simultaneously with the formation of the signal embedded conductor 45a, the ground voltage embedded conductor 45b, and the power supply voltage embedded conductor 45c (see FIG. 26, FIG. 27, FIG. 28, and FIG. 30).

Eight combinations are obtained by the third power of 2 when a set of the mode-set first via hole 44d1 and the mode-set first embedded conductor 15d1 or a set of the mode-set first via hole 44d2 and the mode-set first embedded conductor 45d2 is selected, a set of the mode-set second via hole 44e1 and the mode-set second embedded conductor 45e1 or a set of the mode-set second via hole 44e2 and the mode-set second embedded conductor 45e2 is selected, and a set of the mode-set third via hole 44f1 and the mode-set third embedded conductor 45f1 or a set of the mode-set third via hole 44f2 and the mode-set third embedded conductor 45f2 is selected. Thus, a maximum of eight modes can be set. When the number of lands of one mode-set wiring line 20 is M and the kinds of mode-set wiring lines 20 are N as described above, N-th M combinations are obtained. Here, M can be an integer equal to or more than 2, and N can be an integer equal to or more than 1.

Furthermore, as shown in FIG. 17, a conductive pattern 46 (a signal conductive pattern 46a, a mode-set first conductive pattern 46b*, and a mode-set second conductive pattern 46c*) and a land 47 (a signal land 47a, a ground voltage second land 47b, and a power supply voltage second land 47c) are formed on the front surface of the sealing layer 43 by a method such as a full-additive process, a semi-additive process, or a subtractive process.

In forming the conductive pattern 46 and the land 47, the end of the signal conductive pattern 46a is disposed on the signal embedded conductor 45a, a part (ground voltage second land 47b) of the mode-set first conductive pattern 46b* is disposed on the ground voltage embedded conductor 45b, and a part (power supply voltage second land 47c) of the mode-set second conductive pattern 46c* is disposed on the power supply voltage embedded conductor 45c.

Moreover, in forming the conductive pattern 46 and the land 47, the mode-set first conductive pattern 46b* is disposed so that parts of the mode-set first conductive pattern 46b* may overlap the mode-set electrodes 24d1, 24e1 and 24f1. As a result, when the mode-set first via hole 44d1 and the mode-set first embedded conductor 45d1 are formed, the mode-set first conductive pattern 46b* is conducted to the mode-set first electrode 24d1 by the mode-set first embedded conductor 45d1 (see FIG. 23, FIG. 25, FIG. 26, and FIG. 27). When the mode-set second via hole 44e1 and the mode-set second embedded conductor 45e1 are formed, the mode-set first conductive pattern 46b* is conducted to the mode-set second electrode 24e1 by the mode-set second embedded conductor 45e1 (see FIG. 23, FIG. 24, FIG. 26, and FIG. 28). When the mode-set third via hole 44f1 and the mode-set third embedded conductor 45f1 are formed, the mode-set first conductive pattern 46b* is conducted to the mode-set third electrode 24f1 by the mode-set third embedded conductor 45f1 (see FIG. 23, FIG. 24, FIG. 25, and FIG. 29).

Moreover, in forming the conductive pattern 46 and the land 47, the mode-set second conductive patterns 46c*, 46c*, 46c* are disposed so that the mode-set second conductive patterns 46c*, 46c*, 46c* may respectively overlap the mode-set electrodes 24d2, 24e2 and 24f2. As a result, when the mode-set first via hole 44d2 and the mode-set first embedded conductor 45d2 are formed, the mode-set second conductive pattern 46c* is conducted to the mode-set first electrode 24d2 by the mode-set first embedded conductor 45d2 (see FIG. 24, FIG. 28, FIG. 29, and FIG. 30). When the mode-set second via hole 44e2 and the mode-set second embedded conductor 45e2 are formed, the mode-set second conductive pattern 46c* is conducted to the mode-set second electrode 24e2 by the mode-set second embedded conductor 45e2 (see FIG. 25, FIG. 27, FIG. 29, and FIG. 30). When the mode-set third via hole 44f2 and the mode-set third embedded conductor 45f2 are formed, the mode-set second conductive pattern 46c* is conducted to the mode-set third electrode 24f2 by the mode-set third embedded conductor 45f2 (see FIG. 26, FIG. 27, FIG. 28, and FIG. 30).

In each of FIG. 23 to FIG. 30, that is, in each mode, the same reticle and mask can be used to form the conductive pattern 46 (the signal conductive pattern 46a, the mode-set first conductive pattern 46b*, and the mode-set second conductive pattern 46c*) and the land 47 (the signal land 47a, the ground voltage second land 47b, and the power supply voltage second land 47c).

Furthermore, the method according to the second embodiment is similar to that according to the first embodiment from the step of forming overcoat layers 48 and 49 to the step of dividing (see FIG. 18 to FIG. 20).

As described above, according to the present embodiment, depending on the mode of the semiconductor chip 1 to be manufactured, one of the mode-set first via hole 44d1 and the mode-set first via hole 44d2 is selected and formed, one of the mode-set second via hole 44e1 and the mode-set second via hole 44e2 is selected and formed, and one of the mode-set third via hole 44f1 and the mode-set third via hole 44f2 is selected and formed. In this way, sister products of the semiconductor device 40 different in the mode of the semiconductor chip 1 are created.

Whether to form the mode-set via holes 44d1, 44d2, 44e1, 44e2, 44f1 and 44f2 is determined by whether to apply the laser light 67, and there is no need to use, for example, a different reticle and mask for each mode.

Therefore, when the same semiconductor chip 1 is used to manufacture sister products of the semiconductor device 40 (multiple kinds of semiconductor devices 40) different in the mode of the semiconductor chip 1, there is no need for mode-by-mode mask designing for the conductive pattern 46 (the signal conductive pattern 46a, the mode-set first conductive pattern 46b*, and the mode-set second conductive pattern 46c*) and the land 47 (the signal land 47a, the ground voltage second land 47b, and the power supply voltage second land 47c). Moreover, the mode-set via holes are formed by the laser. Thus, there is no need to use, for example, a different reticle and mask for each mode.

### Modification 1

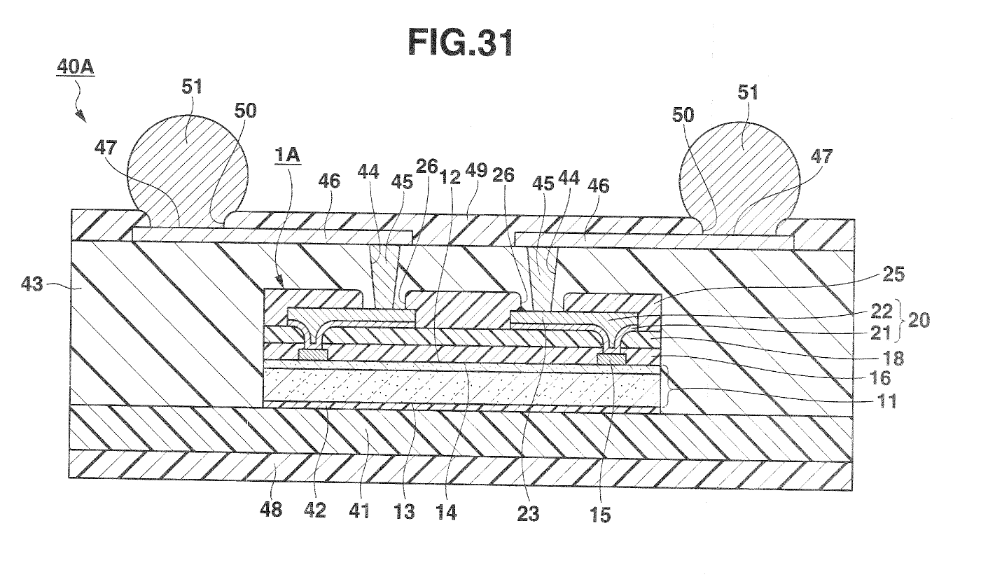

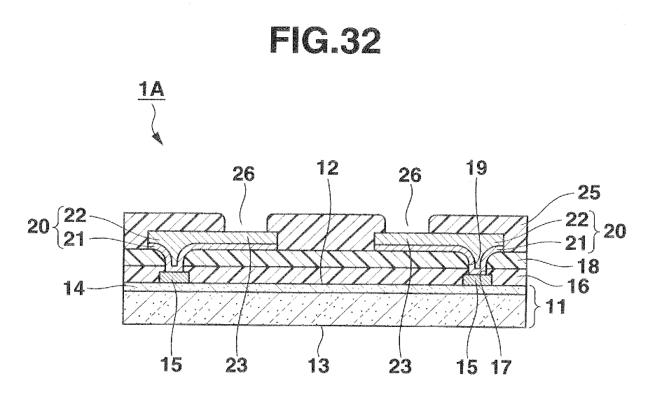

FIG. 31 is a sectional view of a semiconductor device 40A according to Modification 1. FIG. 32 is a sectional view of a semiconductor chip 1A according to Modification 1. While the semiconductor chip 1 shown in FIG. 2 is used to manufacture the semiconductor device 40 shown in FIG. 1 in the first and second embodiments, the semiconductor chip 1A shown in FIG. 32 is used to manufacture the semiconductor device 40A shown in FIG. 31 in Modification 1. The difference between the semiconductor device 40A according to Modification 1 and the semiconductor device 40 according to the first and second embodiments is described below. The same reference numbers are assigned to components in the semiconductor device 40A according to Modification 1 that correspond to those in the semiconductor device 40 according to first and second embodiments.

As shown in FIG. 31 and FIG. 32, the columnar electrodes 24 provided in the semiconductor chip 1 according to the first embodiment are not provided in the semiconductor chip 1A. An opening 26 is formed in a protective layer 25. The opening 26 is located on a land 23, and overlaps the land 23.

As shown in FIG. 32, the land 23 is exposed before the semiconductor chip 1A is embedded. The land 23 (a signal land 23a, a ground voltage first land 23b, a power supply voltage first land 23c, and mode-set wiring line, lands 23d to 23f, 23d1, 23d2, 23e1, 23e2, 23f1 and 23f2) serves as electrode of the semiconductor chip 1A.

As shown in FIG. 31, a part of a sealing layer 43 is embedded in the opening 26 after the semiconductor chip 1A is embedded. A via hole 44 formed in the sealing layer 43 reaches the land 23 through the opening 26. Thus, an embedded conductor 45 embedded in the via hole 44 is connected to the land 23.

The thickness of the protective layer 25 is smaller than the first embodiment.

The components in the semiconductor device 40A according to Modification 1 that correspond to those in the semiconductor device 40 according to the first and second embodiments are provided in a similar manner except for the points described below.

The procedure of manufacturing the semiconductor device 40A by using the semiconductor chip 1A is the same as the procedure of manufacturing the semiconductor device 10 by using the semiconductor chip 1 as in the first and second embodiments. When prepregs 64 and 66 (see FIG. 13) are heated and pressured during the manufacturing process of the semiconductor device 40A, the prepregs 64 and 66 are partly embedded in the opening 26. When the via hole 44 is formed by the application of laser light 67 (see FIG. 15) during the manufacturing process of the semiconductor device 40A, the via hole 44 is extended up to the land 23 to expose the land 23. The embedded conductor 45 is embedded in the via hole 44 during the manufacturing process of the semiconductor device 40A so that the embedded conductor 45 contacts and is conducted to the land 23.

When the electrode 24 is not present in the first embodiment, it goes without saying that mode-set via holes 44d to 44f are selectively formed in the sealing layer 43 as in the manufacturing method according to the first embodiment. Alternatively, when the electrode 24 is not present in the second embodiment, it goes without saying that one of a mode-set first via hole 44d1 and a mode-set first via hold 44d2 is formed in the sealing layer 43, one of a mode-set second via hole 44e1 and a mode-set second via hole 44e2 is formed in the sealing layer 43, and one of a mode-set third via hole 44f1 and a mode-set third via hole 44f2 is formed in the sealing layer 43, as in the manufacturing method according to the second embodiment.

While the opening 26 is formed in the protective layer 25 before the formation of the via hole 44 in the above explanation, the opening 26 may not be formed in the protective layer 25 before the formation of the via hole 44. In this case, before the semiconductor chip 1A is embedded, the land 23 is covered with the protective layer 25 and is not exposed. When the semiconductor device 40A is manufactured by using the semiconductor chip 1A in which the opening 26 is not formed, the protective layer 25 is thin owing to the absence of the electrode 24. Thus, the via hole 44 is formed in the sealing layer 43 and the protective layer 25 by laser so that the via hole 44 reaches the land 23 from the front surface of the sealing layer 43.

### Modification 2

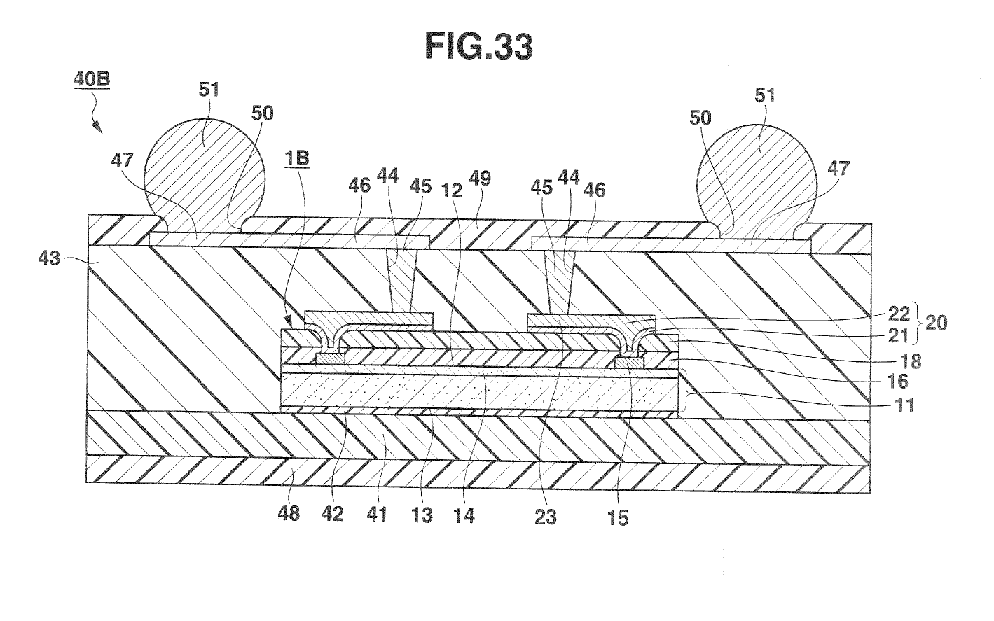

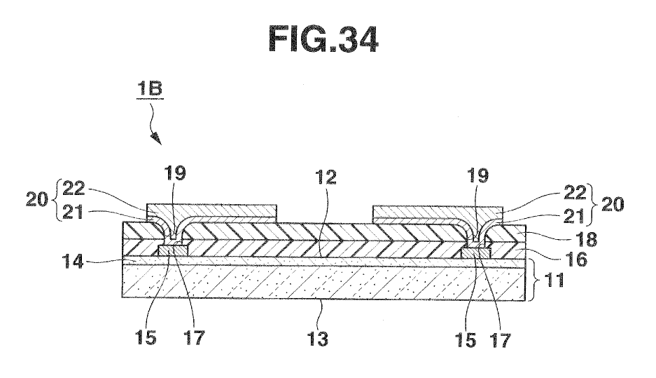

FIG. 33 is a sectional view of a semiconductor device 40B according to Modification 2. FIG. 34 is a sectional view of a semiconductor chip 1B according to Modification 2. In Modification 2, the semiconductor device 40B shown in FIG. 33 is manufactured by using the semiconductor chip 1B shown in FIG. 34. The difference between the semiconductor device 40B according to Modification 2 and the semiconductor device 40 according to the first and second embodiments is described below. The same reference numbers are assigned to components in the semiconductor device 40B according to Modification 2 that correspond to those in the semiconductor device 40 according to first and second embodiments.

As shown in FIG. 33 and FIG. 34, the electrode 24 and the protective layer 25 provided in the semiconductor chip 1 according to the first embodiment are not provided in the semiconductor chip 1B. As shown in FIG. 34, before the semiconductor chip 1B is embedded, a wiring line 20 and a land 23 are exposed. The land 23 (a signal land 23a, a ground voltage first land 23b, a power supply voltage first land 23c, and mode-set wiring line lands 23d to 23f, 23d1, 23d2, 23e1, 23e2, 23f1 and 23f2) serves as electrode of the semiconductor chip 1B.

As shown in FIG. 33, after the semiconductor chip 1B is embedded, a part of a sealing layer 43 is stacked on an insulating film 18, and the wiring line 20 is covered with the sealing layer 43. The via hole 44 formed in the sealing layer 43 reaches the land 23. Thus, an embedded conductor 45 embedded in the via hole 44 is connected to the land 23.

The components in the semiconductor device 40B according to Modification 2 that correspond to those in the semiconductor device 40 according to the first and second embodiments are provided in a similar manner except for the points described below.

The procedure of manufacturing the semiconductor device 40B by using the semiconductor chip 1B is the same as the procedure of manufacturing the semiconductor device 40 by using the semiconductor chip 1 as in the first and second embodiments. When prepregs 64 and 66 (see FIG. 13) are heated and pressured during the manufacturing process of the semiconductor device 40B, the wiring line 20 and the protective layer 25 are covered with the prepregs 64 and 66. When the via hole 44 is formed by the application of laser light 67 (see FIG. 15) during the manufacturing process of the semiconductor device 40B, the via hole 44 is extended up to the land 23 to expose the land 23. The embedded conductor 45 is embedded in the via hole 44 during the manufacturing process of the semiconductor device 40B so that the embedded conductor 45 contacts the land 23.

When the electrode 24 and the protective layer 25 are not present in the first embodiment, it goes without saying that mode-set via holes 44d to 44f are selectively formed in the sealing layer 43 as in the manufacturing method according to the first embodiment. Alternatively, when the electrode 24 and the protective layer 25 are not present in the second embodiment, it goes without saying that one of a mode-set first via hole 44d1 and a mode-set first via hole 44d2 is formed, one of a mode-set second via hole 44e1 and a mode-set second via hole 4 is formed in the sealing layer 45, and one of a mode-set third via hole 44f1 and a mode-set third via hole 44f2 is formed in the sealing layer 43, as in the manufacturing method according to the second embodiment.

### Modification 3

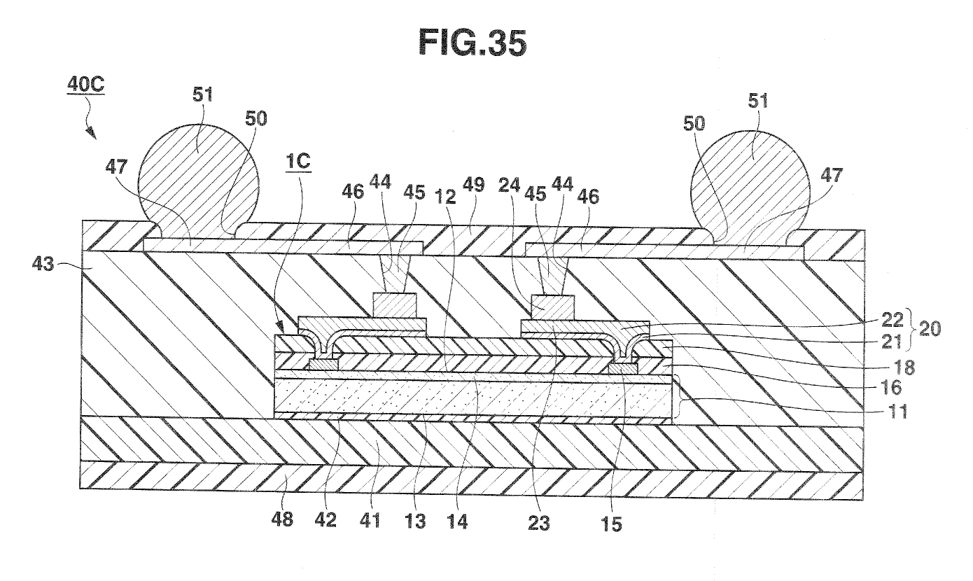

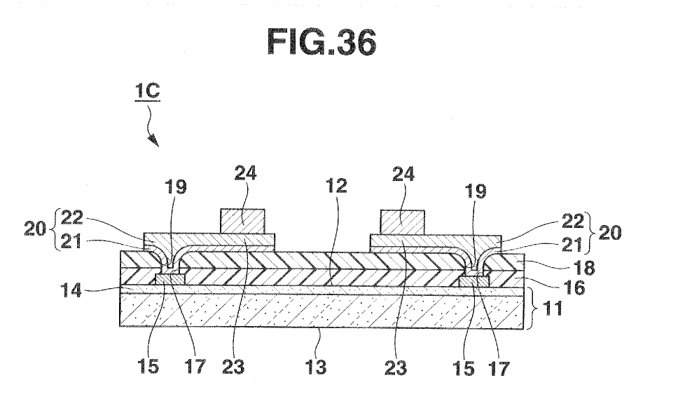

FIG. 35 is a sectional view of a semiconductor device 40C according to Modification 3. FIG. 36 is a sectional view of a semiconductor chip 1C according to Modification 3. In Modification 3, the semiconductor device 40C shown in FIG. 35 is manufactured by using the semiconductor chip 1C shown in FIG. 36. The difference between the semiconductor device 40C according to Modification 3 and the semiconductor device 40 according to the first and second embodiments is described below. The same reference numbers are assigned to components in the semiconductor device 40C according to Modification 3 that correspond to those in the semiconductor device 40 according to first and second embodiments.

As shown in FIG. 35 and FIG. 36, the protective layer 25 in the semiconductor chip 1 according to the first embodiment is not provided in the semiconductor chip 10. As shown in FIG. 36, before the semiconductor chip 10 is embedded, a wiring, line 20, a land 23, and an electrode 24 are exposed.

As shown in FIG. 35, after the semiconductor chip 1C is embedded, a part of a sealing layer 43 is stacked on an insulating film 18, and the wiring line 20 and the electrode 24 are covered with the sealing layer 43. The side surface of the electrode 24 is protected by the sealing layer 43. A via hole 44 formed in the sealing layer 43 reaches the electrode 24. Thus, an embedded conductor 45 embedded in the via hole 44 is connected to the electrode 24.

The components in the semiconductor device 40C according to Modification 3 that correspond to those in the semiconductor device 40 according to the first and second embodiments are provided in a similar manner except for the points described below.

The procedure of manufacturing the semiconductor device 40C by using the semiconductor chip 1C is the same as the procedure of manufacturing the semiconductor device 40 by using the structure of the semiconductor chip 1 according to the first and second embodiments from which the protective layer 25 is eliminated. When prepregs 64 and 66 (see FIG. 13) are heated and pressured during the manufacturing process of the semiconductor device 40C, the sealing layer 43 is formed so that the wiring line 20 and the side surface and front surface of the electrode 24 are covered with the prepregs 64 and 66.

In the embodiments and modifications described above, the conductive pattern 46 may be formed by the following step after the via hole 44 shown in FIG. 15 is formed.

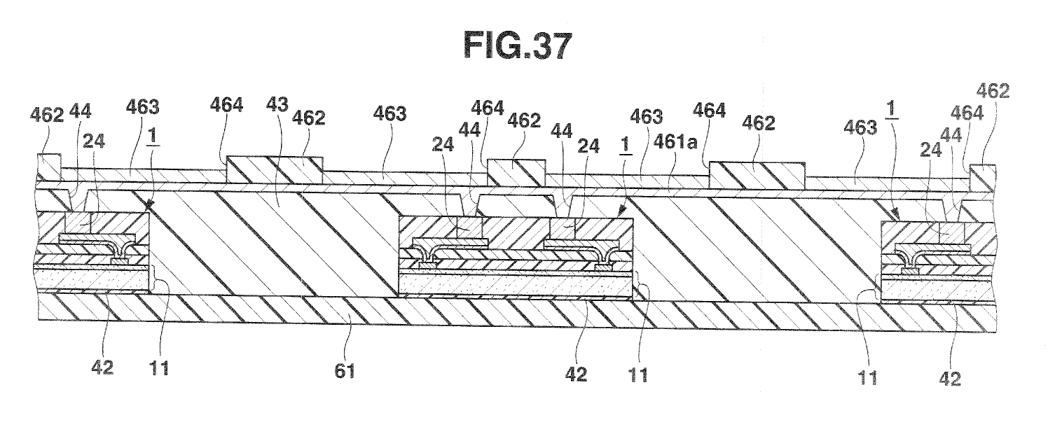

That is, as shown in FIG. 37, a foundation metal layer formation film 461a is formed on the upper surface of the electrode 24 of the semiconductor chip 1 exposed through the via hole 44 of the sealing layer 43 and on the entire upper surface of the sealing layer 43. In this case, the foundation metal layer formation film 461a may only be a copper layer formed by electroless plating, may only be a copper layer formed by sputtering, or may be a copper layer formed by sputtering on a thin film layer of, for example, titanium formed by sputtering.

A plating resist film 462 is then patterned/formed on the upper surface of the foundation metal layer formation film 461a. In this case, an opening 464 is formed in a part of the plating resist film 462 corresponding to a region where an upper metal layer 463 is to be formed. Further, electrolytic plating with copper is carried out using the foundation metal layer formation film 461a as a plating current path, thereby forming the upper metal layer 463 on the upper surface of the foundation metal layer formation film 461a within the opening 464 in the plating resist film 462.

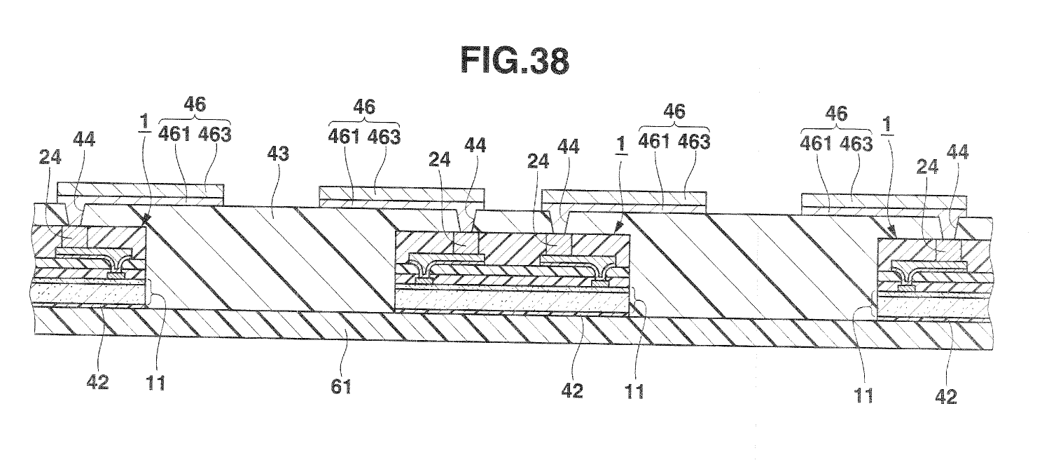

The plating resist film 462 is then released. Further, using the upper metal layer 463 as a mask, the foundation metal layer formation film 461a located in a region other than a region under the upper metal layer 463 is etched and removed. Thus, as shown in FIG. 38, a foundation metal layers 461 remains in the region immediately under the upper metal layer 463 alone. In this way, the conductive pattern 46 connected to the upper surface of the electrode 24 of the semiconductor chip 1 exposed through the via hole 44 of the sealing layer 43 may be formed by the upper metal layer 463 and by the foundation metal layer 461 remaining in the region immediately under the upper metal layer 463.

After the conductive pattern 46 is thus formed, the procedure further returns to the step of patterning the overcoat layer 49 shown in FIG. 18.

When the conductive pattern 46 is formed by the method described above, the conductive pattern 46 connected to the upper surface of the electrode 24 of the semiconductor chip 1 exposed through the via hole 44 of the sealing layer 43 can be simultaneously formed in the via hole 44 of the sealing layer 43 and on the upper surface of the sealing layer 43. Therefore, there is no need to form the embedded conductor 45 and the conductive pattern 46 in separate steps.

When the protective layer 25 is not present in the first embodiment, it goes without saying that mode-set via holes 44d to 44f are selectively formed in the sealing layer 43 as in the manufacturing method according to the first embodiment. Alternatively, when the protective layer 25 is not present in the second embodiment, it goes without saying that one of a mode-set first via hole 44d1 and a mode-set first via hole 44d2 is formed, one of a mode-set second via hole 44e1 and a mode-set second via hole 44e2 is formed in the sealing layer 43, and one of a mode-set third via hole 44f1 and a mode-set third via hole 44f2 is formed in the sealing layer 43, as in the manufacturing method according to the second embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor chip which comprises mode-set terminals, and mode-set wiring lines respectively connected to the mode-set terminals;
a sealing layer which covers the semiconductor chip and a land of a first mode-set wiring line which is one of the mode-set wiring lines, the sealing layer including a mode-set via hole formed above a land of a second mode-set wiring line, the second mode-set wiring line being one of the mode-set wiring lines and being different from the first mode-set wiring line;
a mode-set embedded conductor which is provided within the mode-set via hole and which is provided to be connected to the second mode-set wiring line; and
a mode-set conductive pattern which is connected to the mode-set embedded conductor and which is provided on the sealing layer above the land of the first mode-set wiring line.

2. The semiconductor device according to claim 1, wherein the first mode-set wiring line and the mode-set terminal connected to the first mode-set wiring line are set in a nonconnected state, and
the second mode-set wiring line and the mode-set terminal connected to the second mode-set wiring line are set in a predetermined voltage set state via the mode-set embedded conductor and the mode-set conductive pattern.

3. The semiconductor device according to claim 2, wherein the predetermined voltage is one of a ground voltage and a power supply voltage different from the ground voltage.

4. The semiconductor device according to claim 3, wherein the mode-set conductive pattern is one of a ground voltage conductive pattern and a power supply voltage conductive pattern.

5. The semiconductor device according to claim 2, wherein the mode-set conductive pattern is connected to a bump, and the predetermined voltage is applied to the mode-set conductive pattern via the bump.

6. The semiconductor device according to claim 1, wherein a first mode-set electrode which is one of mode-set electrodes and the sealing layer intervene between the land of the first mode-set wiring line and the mode-set conductive pattern located above the land of the first mode-set wiring line, and
a second mode-set electrode and the mode-set embedded conductor intervene between the land of the second mode-set wiring line and the mode-set conductive pattern located above the land of the second mode-set wiring line, the second mode-set electrode being one of the mode-set electrodes and being different from the first mode-set electrode.

7. The semiconductor device according to claim 1, wherein the semiconductor chip comprises terminals, and wiring lines respectively connected to the terminals,
the sealing layer comprises via holes respectively formed above lands of the wiring lines,
embedded conductors are respectively formed within the via holes, and
conductive patterns respectively connected to the embedded conductors are provided on the sealing layer.

8. The semiconductor device according to claim 7, wherein when viewed from above the conductive patterns, the mode-set via hole and the mode-set embedded conductor are disposed between a land of the mode-set conductive pattern and a land of one of the conductive patterns or between two lands of any two of the conductive patterns.

9. The semiconductor device according to claim 1, wherein modes each corresponding to the state of a voltage set in the mode-set terminals and being set to be different from one another include an initial clock setting after power on reset of the semiconductor chip, a memory bus width setting, a data alignment setting, and an operation mode setting of the semiconductor chip.

10. A semiconductor device manufacturing method comprising:
forming a sealing layer on a semiconductor chip which comprises mode-set terminals, and mode-set wiring lines respectively connected to the mode-set terminals, the sealing layer being formed to cover a land of a first mode-set wiring line which is one of the mode-set wiring lines and a land of a second mode-set wiring line which is one of the mode-set wiring lines and which is different from the first mode-set wiring line;
forming a mode et via hole in the sealing layer above the land of the second mode-set wiring line; and
forming a mode-set conductive pattern which is connected to the land of the second mode-set wiring line through the mode-set via hole and which is provided on the sealing layer above the land of the first mode-set wiring line.

11. The semiconductor device manufacturing method according to claim 10, further comprising:
forming a mode-set embedded conductor within the mode-set via hole to be connected to the land of the second mode-set wiring line; and
forming a mode-set conductive pattern which is connected to the mode-set embedded conductor above the land of the second mode-set wiring line and which is provided on the sealing layer above the land of the first mode-set wiring line.

12. The semiconductor device manufacturing method according to claim 10, wherein laser light is applied to the sealing layer above the land of the second mode-set wiring line to form the mode-set via hole.

13. The semiconductor device manufacturing method according to claim 10, wherein the first mode-set wiring line and the mode-set terminal connected to the first mode-set wiring line are set in a nonconnected state, and
the second mode-set wiring line and the mode-set terminal connected to the second mode-set wiring line are set in a predetermined voltage set state via the mode-set embedded conductor and the mode-set conductive pattern.

14. The semiconductor device manufacturing method according to claim 13, wherein the predetermined voltage is one of a ground voltage and a power supply voltage different from the ground voltage.

15. The semiconductor device manufacturing method according to claim 13, further comprising forming, to be connected to the mode-set conductive pattern, a bump used to apply the predetermined voltage.

16. The semiconductor device manufacturing method according to claim 14, wherein the mode-set conductive pattern is one of a ground voltage conductive pattern and a power supply voltage conductive pattern.

17. The semiconductor device manufacturing method according to claim 10, wherein the semiconductor chip includes a first mode-set electrode formed on the land of the first mode-set wiring line, and a second mode-set electrode formed on the land of the second mode-set wiring line, the first mode-set electrode being one of mode-set electrodes, the second mode-set electrode being one of the mode-set electrodes and being different from the first mode-set electrode, and
the sealing layer is formed on the first mode-set electrode and the second mode-set electrode.

18. The semiconductor device manufacturing method according to claim 10, wherein the semiconductor chip comprises terminals, and wiring lines respectively connected to the terminals,
forming via holes in the sealing layer to be respectively provided above lands of the wiring lines,
forming embedded conductors to be respectively provided within the via holes, and
forming, on the sealing layer, conductive patterns respectively connected to the embedded conductors.

19. The semiconductor device manufacturing method according to claim 17, wherein when viewed from above the conductive patterns, the mode-set via hole and the mode-set embedded conductor are disposed between a land of the mode-set conductive pattern and a land of one of the conductive patterns or between lands of any two of the conductive patterns.

20. A semiconductor device comprising:
a semiconductor chip which comprises a mode-set terminal and a mode-set wiring line, the mode-set wiring line including at least a first land and a second land and being connected to the mode-set terminal;
a sealing layer which covers the semiconductor chip and one of the first land and the second land of the mode-set wiring line, the sealing layer including a mode-set via hole formed above the other of the first land and the second land of the mode-set wiring line;
a mode-set embedded conductor which is provided within the mode-set via hole and which is provided to be connected to the other land of the mode-set wiring line; and
mode-set conductive patterns provided on the sealing layer,
wherein a first mode-set conductive pattern which is one of the mode-set conductive patterns is provided on the sealing layer above the one land of the mode-set wiring line, and a second mode-set conductive pattern which is one of the mode-set conductive patterns and which is different from the first mode-set conductive pattern is connected to the mode-set embedded conductor.

21. The semiconductor device according to claim 20, wherein one of a first predetermined voltage and a second predetermined voltage different from the first predetermined voltage is applied to the first mode-set conductive pattern, the other of the first predetermined voltage and the second predetermined voltage is applied to the second mode-set conductive pattern, and
the other of the first predetermined voltage and the second predetermined voltage is applied to the mode-set terminal via the mode-set wiring line, the other land, the mode-set embedded conductor, and the second mode-set conductive pattern.

22. The semiconductor device according to claim 21, wherein the first predetermined voltage is a ground voltage, and the second predetermined voltage is a power supply voltage different from the ground voltage.

23. The semiconductor device according to claim 20, wherein a first mode-set electrode which is one of mode-set electrodes and the sealing layer intervene between the one land of the mode-set wiring line and the first mode-set conductive pattern, and
a second mode-set electrode and the mode-set embedded conductor intervene between the other land of the mode-set wiring line and the second mode-set conductive pattern, the second mode-set electrode being one of the mode-set electrodes and being different from the first mode-set electrode.

24. The semiconductor device according to claim 20, wherein the semiconductor chip comprises terminals, and wiring lines respectively connected to the terminals,
the sealing layer comprises via holes respectively formed above lands of the wiring lines,
embedded conductors are respectively formed within the via holes, and
conductive patterns respectively connected to the embedded conductors are provided on the sealing layer.

25. The semiconductor device according to claim 21, wherein the mode-set conductive pattern is connected to a bump, and the other predetermined voltage is applied to the mode-set conductive pattern via the bump.

26. The semiconductor device according to claim 20, wherein modes each corresponding to the state of a voltage set in the mode-set terminals and being set to be different from one another include an initial clock setting after power on reset of the semiconductor chip, a memory bus width setting, a data alignment setting, and an operation mode setting of the semiconductor chip.

27. A semiconductor device manufacturing method comprising:
forming a sealing layer on a semiconductor chip which comprises a mode-set terminal, and a mode-set wiring line including at least a first land and a second land and connected to the mode-set terminal, the sealing layer being formed to cover the first land and the second land of the mode-set wiring line;
forming a mode-set via hole above one of the first land and the second land of the mode-set wiring line; and
forming mode-set conductive patterns on the sealing layer,
wherein the mode-set conductive patterns are formed so that a first mode-set conductive pattern is provided on the sealing layer above the other land which is one of the first land and the second land of the mode-set wiring line and which is different from the one land and so that a second mode-set conductive pattern is connected to the one land of the mode-set wiring line through the mode-set via hole, the first mode-set conductive pattern being one of the mode-set conductive patterns, the second mode-set conductive pattern being one of the mode-set conductive patterns and being different from the first mode-set conductive pattern.

28. The semiconductor device manufacturing method according to claim 26, further comprising:
forming a mode-set embedded conductor within the mode-set via hole to be connected to the one land of the mode-set wiring line,
wherein the mode-set conductive patterns are formed so that the second mode-set conductive pattern is connected to the mode-set embedded conductor above the one land of the mode-set wiring line.

29. The semiconductor device manufacturing method according to claim 27, wherein laser light is applied to the sealing layer above the one land of the mode-set wiring line to form the mode-set via hole.

30. The semiconductor device manufacturing method according to claim 27, wherein the first mode-set conductive pattern is a conductive pattern to which one of a first predetermined voltage and a second predetermined voltage different from the first predetermined voltage is applied, and the second mode-set conductive pattern is a conductive pattern to which the other of the first predetermined voltage and the second predetermined voltage is applied.

31. The semiconductor device manufacturing method according to claim 30, wherein the first predetermined voltage is a ground voltage, and the second predetermined voltage is a power supply voltage different from the ground voltage.

32. The semiconductor device manufacturing method according to claim 30, further comprising forming, to be connected to the mode-set conductive pattern, a bump used to apply the other predetermined voltage.

33. The semiconductor device manufacturing method according to claim 27, further comprising:
forming, on the other land of the mode-set wiring line, a first mode-set electrode which is one of mode-set electrodes, and, on the one land of the mode-set wiring line, a second mode-set electrode which is one of the mode-set electrodes and which is different from the first mode-set electrode, and
wherein the first mode-set electrode remains covered with the sealing layer, and the mode-set via hole is formed in the sealing layer above the second mode-set electrode, and then the mode-set embedded conductor is formed in the mode-set via hole.

34. The semiconductor device manufacturing method according to claim 27, wherein the semiconductor chip comprises terminals, and wiring lines respectively connected to the terminals,
forming via holes in the sealing layer to be respectively provided above lands of the wiring lines,
forming embedded conductors to be respectively provided within the via holes, and
forming, on the sealing layer, conductive patterns respectively connected to the embedded conductors.
